(19) United States
(12) Patent Application Publication
(10) Pub. No.: US 2015/0243858 A1
(43) Pub. Date: Aug. 27, 2015

(54) Surface Treatment Agent For Optical Material, And Optical Material

(71) Applicant: DOW CORNING TORAY CO., LTD., Tokyo (JP)

(72) Inventors: Tadashi Okawa, Ichihara-shi (JP); Kazuhiko Kojima, Ichihara-shi (JP); Tomohiro Iimura, Ichihara-shi (JP); Haruhiko Furukawa, Ichihara-shi (JP)

(21) Appl. No.: 14/428,752

(22) PCT Filed: Sep. 20, 2013
(86) PCT No.: PCT/JP2013/076452

§ 371 Date: Mar. 17, 2015

(30) Foreign Application Priority Data
Sep. 21, 2012 (JP) 2012-208701
Jul. 4, 2013 (JP) 2013-141089

(51) Int. Cl. H01L 33/56; C08L 83/04; H01L 33/50; C07F 7/18; H01L 33/58; C08G 77/20; C09K 11/02

(52) U.S. Cl. CPC H01L 33/56; C08G 77/20; C08L 83/04; C09K 11/02; C07F 7/1836; C07F 7/1844; H01L 33/58; H01L 33/502; H01L 2933/0091; H01L 2933/005; H01L 2933/0058; H01L 2933/0041

(57) ABSTRACT

A surface treatment agent for an optical material comprising an organic silicon compound having a functional group selected from a highly polar functional group, a hydroxyl group-containing group, a silicon atom-containing hydrolyzable group, or metal salt derivatives thereof bonded to silicon atoms directly or via a functional group with a valency of (n+1) (n is a number equal to 1 or greater); and having at least one structure in the molecule in which the silicon atoms are bonded to any siloxane unit represented by R¹₃SiO_{1/2}, R¹₂SiO_{2/2}, R¹SiO_{3/2}, and SiO_{4/2}.

### TECHNICAL FIELD

Priorities are claimed on Japanese Patent Application No. 2012-208701 and No. 2013-141089, filed on Sep. 21, 2012 and Jul. 4, 2013, the content of which are incorporated herein by reference.

The present invention relates to a surface treatment agent for various members used in optical materials and more particularly to a silicon-based surface treatment agent for an optical material which has excellent thermal stability, wherein the surface of an optical fine member having a microparticulate or highly refined structure can be modified so as to have hydrophobicity, fine dispersibility, and dispersion stability, and an optical material produced using the same.

### BACKGROUND ART

Conventionally, the use of various hydrolyzable silanes, alkoxysilyl group-containing siloxane compounds, silazane compounds, and siloxanes having isopropenoxysilyl groups has been proposed as surface treatment agents for fillers such as silica, talc, clay, aluminum hydroxide, and titanium oxide (for example, see Patent Document 1 and the like). In addition, the present inventors have proposed the use of carboxylic acid-modified silicones (see Patent Document 2) as powder treatment agents for cosmetic compositions. However, there is no mention of a surface treatment agent used in an optical fine member in these documents.

On the other hand, in recent years, fine members such as fluorescent microparticles, metal oxide microparticles, metal microparticles, nanocrystal structures, or quantum dots have been used in optical material applications such as light-emitting diodes (LEDs) in order to secure or improve the functionality thereof, but these optical fine members have high surface hydrophilicity in the untreated state, which may cause aggregation or poor dispersion into a matrix of another hydrophobic resin or the like. In particular, metal oxide microparticles having a high refractive index and a particle size so small that light scattering can be ignored are useful for obtaining optical materials with a high refractive index, but it is difficult to finely and stably disperse these optical fine members into silicone resins with high hydrophobicity. Therefore, several treatment methods have been proposed in order to solve these problems (see Patent Documents 3 to 7).

For example, a dimethylsilicone filler treatment agent capped at one terminal by a vinyl group and at the other terminal by a hydrolyzable silyl group is proposed in Patent Document 3 (Japanese Unexamined Patent Application Publication No. 2011-026444), but since the refractive index of the dimethylsilicone part is low, it is unsuitable for obtaining a composition with a high refractive index. Similarly, the use of a dimethylsilicone-based filler treatment agent having a silicon-bonded alkoxysilyl ethyl group as a side chain is proposed in Patent Document 4 (Japanese Unexamined Patent Application Publication No. 2010-241935), but since the refractive index of the dimethylsilicone portion is low, it is unsuitable for obtaining a composition with a high refractive index.

On the other hand, metal oxide microparticles treated by a surface modifier containing a silane compound having an alkenyl group with from 4 to 20 carbon atoms is proposed in Patent Document 5 (Japanese Unexamined Patent Application Publication No. 2010-195646), but there was the problem that the metal oxide particles potentially have poor thermal stability after this treatment.

Further, in Patent Document 6 (Japanese Unexamined Patent Application Publication No. 2010-144137), a silicone resin composition is proposed, the silicone resin composition being obtained by performing a polymerization reaction on a silicone derivative having an alkoxysilyl group at the molecular terminal or a side chain and metal oxide microparticles having reactive functional groups on the microparticle surface, wherein the alkoxysiyl group is a silyl group having an alkoxy group and an aromatic group as functional groups directly bonded to silicon. However, since the alkoxy group and the aromatic group are present on the same silicon atom, the reactivity of this alkoxysilyl group with the reactive functional groups on the surface of the microparticles is low, which leads to the problem that sufficient modification effects are difficult to achieve.

Further, in Patent Document 7 (WO10026992), a diphenyl dimethyl silicone having a vinyl group and a trimethoxysilyl ethyl group at the terminals is given as an example of a silicone chain-containing dispersing agent in a composition having metal oxide microparticles treated with a silicone chain-containing dispersing agent and a silicone resin. This dispersing agent had a problem with safety in that it was necessary to use very highly toxic trimethoxysilane when introducing a trimethoxysilyl group. Further, the substance was not yet satisfactory for modifying the surface of the optical fine member so as to have hydrophobicity, fine dispersibility, and dispersion stability and was not satisfactory with regard to the refractive index of the silicone resin that is ultimately obtained.

### PRIOR ART DOCUMENTS

### Patent Documents

Patent Document 1: Japanese Unexamined Patent Application Publication No. 2000-327784
Patent Document 2: WO2009/022621
Patent Document 3: Japanese Unexamined Patent Application Publication No. 2011-026444
Patent Document 4: Japanese Unexamined Patent Application Publication No. 2010-241935
Patent Document 5: Japanese Unexamined Patent Application Publication No. 2010-195646
Patent Document 6: Japanese Unexamined Patent Application Publication No. 2010-144137
Patent Document 7: WO2010/026992

### SUMMARY OF INVENTION

### Technical Problem

An object of the present invention is to provide a novel surface treatment agent for an optical material. More specifically, an object of the present invention is to provide a surface treatment agent for an optical material which has excellent thermal stability and affinity with other curable resins and which can hydrophobically modify the surface of an optical fine member as necessary, for example, and can, in particular, substantially modify the fine dispersibility and dispersion stability in hydrophobic resins. Another object of the present invention is to provide an optical material containing a member which is surface-treated by this surface treatment agent for an optical material.

### Solution to Problem

As a result of intensive investigation aimed at achieving the above objects, the present inventors arrived at the present invention. That is, the object of the present invention is achieved by a surface treatment agent for an optical material containing an organic silicon compound having a functional group selected from a highly polar functional group, a hydroxyl group-containing group, a silicon atom-containing hydrolyzable group, or metal salt derivatives thereof bonded to silicon atoms directly or via a functional group and having at least one structure in the molecule in which the silicon atoms are bonded to other siloxane units. In particular, the object of the present invention is more preferably achieved by a surface treatment agent for an optical material containing an organic silicon compound having a constant number of other hydrophobic siloxane units in the molecule and having a functional group selected from a highly polar functional group, a hydroxyl group-containing group, a silicon atom-containing hydrolyzable group, or metal salt derivatives thereof bonded to silicon atoms directly or via a monovalent or divalent functional group.

In addition, the object of the present invention is preferably achieved by an optical fine member treated using the surface treatment agent for an optical material described above and an optical material containing the same. Similarly, the object of the present invention is preferably achieved by a production method for a microparticulate optical fine member in which the surface treatment agent for an optical material described above is used in the production step (liquid-phase method, solid-phase method, or post-treatment method) thereof.

Specifically, the object of the present invention is achieved by:

“[1] A surface treatment agent for an optical material comprising an organic silicon compound having: a functional group selected from a highly polar functional group, a hydroxyl group-containing group, a silicon atom-containing hydrolyzable group, or metal salt derivatives thereof bonded to silicon atoms directly or via a functional group with a valency of (n+1) (where n is a number equal to 1 or greater) and
having at least one structure in the molecule in which the silicon atoms are bonded to any siloxane unit represented by R¹₃SiO_{1/2}, R¹₂SiO_{2/2}, R¹SiO_{3/2}, and SiO_{4/2} (wherein R¹ is a substituted or unsubstituted monovalent hydrocarbon group, a hydrogen atom, a halogen atom, a hydroxyl group, an alkoxy group, or a functional group selected from a highly polar functional group, a hydroxyl group-containing group, a silicon atom-containing hydrolyzable group, or metal salt derivatives thereof bonded to silicon atoms via a functional group with a valency of (n+1)).
[2] The surface treatment agent for an optical material according to [1], wherein the organic silicon compound has at least one structure represented by the following formula in the molecule and has from 2 to 1,000 silicon atoms in the molecule.

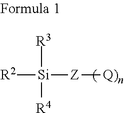

(wherein, Z is a direct bond to a silicon atom or a functional group with a valency of (n+1);
n is a number equal to 1 or greater;
Q is a functional group selected from a highly polar functional group, a hydroxyl group-containing group, a hydrolyzable group, or metal salt derivatives thereof; and
R² to R⁴ are each independently substituted or unsubstituted monovalent hydrocarbon groups, hydrogen atoms, halogen atoms, hydroxyl groups, alkoxy groups, or divalent functional groups bonding to binding sites for oxygen atoms (—O—) in any of the siloxane units represented by R¹₃SiO_{1/2}, R¹₂SiO_{2/2}, R¹SiO_{3/2}, and SiO_{4/2} or silicon atoms (Si) in the same siloxane unit, at least one of R² to R⁴ being a binding site for oxygen atoms (—O—) in any of the siloxane units represented by R¹₃SiO_{1/2}, R¹₂SiO_{2/2}, R¹SiO_{3/2}, and SiO_{4/2}; and R¹ is synonymous with that described above).
[3] The surface treatment agent for an optical material according to claim [1] or [2], wherein the organic silicon compound is an organic silicon compound represented by the following average structural formula:

(R^{M}₃SiO_{1/2})ₐ(R^{D}₂SiO_{2/2})_{b}(R^{T}SiO_{3/2})_{c}(SiO_{4/2})_{d}

(wherein R^{M}, R^{D}, and R^{T} are each independently
monovalent hydrocarbon groups, hydrogen atoms, hydroxyl groups, alkoxy groups, groups having functional groups (Q) selected from highly polar functional groups, hydroxyl group-containing groups, silicon atom-containing hydrolyzable groups, or metal salt derivatives thereof bonded to silicon atoms directly or via functional groups with a valency of (n+1) represented by —Z-(Q)n described above, or divalent functional groups bonded to the Si atoms of other siloxane units;
at least 50 mol % of all of the R^{M}, R^{D}, and R^{T} moieties are monovalent hydrocarbon groups; the groups containing at least one group represented by —Z-(Q)n in the molecule; and n is a number equal to 1 or greater, a to d are respectively 0 or positive numbers, and a+b+c+d is a number within a range of 2 to 1,000).
[4] The surface treatment agent for an optical material according to any one of [1] to [3], wherein the organic silicon compound is an organic silicon compound represented by the following average structural formula:

(R^{M1}₃SiO_{1/2})ₐ₁(R^{D1}₂SiO_{2/2})_{b1}(R^{T1}SiO_{3/2})_{c1}(SiO_{4/2})_{d1}

(wherein R^{M1}, R^{D1}, and R^{T1} are each independently selected from:
monovalent hydrocarbon groups, hydrogen atoms, hydroxyl groups, alkoxy groups, groups having functional group (Q) selected from highly polar functional groups, hydroxyl group-containing groups, silicon atom-containing hydrolyzable groups, or metal salt derivatives thereof bonded to silicon atoms via divalent functional groups (Z¹) represented by —Z¹-Q;
groups represented by -A-(R^{D2}₂SiO)ₑ₁R^{D2}₂Si—Z¹-Q (wherein A is a divalent hydrocarbon group, R^{D2} is an alkyl group or a phenyl group, e1 is a number within the range of 1 to 50, and Z¹ and Q are synonymous with those described above);
groups represented by -A-(R^{D2}₂SiO)ₑ₁SiR^{M2}₃ (wherein A, R^{D2}, Z¹, and Q are synonymous with those described above, R^{M2} is an alkyl group or a phenyl group, and e1 is the same number as described above); or
groups represented by —O—Si(R^{D3})₂—X¹ (wherein R^{D3} is an alkyl group having from 1 to 6 carbon atoms or a phenyl group, and X¹ is a silylalkyl group represented by the following general formula (2) when i=1):

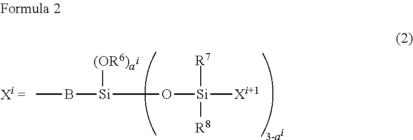

(wherein R⁶ is a hydrogen atom or an alkyl group having from 1 to 6 carbon atoms or a phenyl group, and R⁷ or R⁸ is a hydrogen atom or an alkyl group having from 1 to 6 carbon atoms or a phenyl group; B is a straight-chain or branched-chain alkylene group represented by CᵣH₂; r is an integer from 2 to 20;
i represents the hierarchies of a silylalkyl group represented by Xⁱ, which is an integer from 1 to c when the number of hierarchies is c; the number of hierarchies c is an integer from 1 to 10; aⁱ is an integer from 0 to 2 when i is 1 and is a number less than 3 when i is 2 or greater; Xⁱ⁺¹ is a silylalkyl group when i is less than c and is a methyl group (—CH₃) when i=c).
wherein at least 50 mol % of all of the R^{M1}, R^{D1}, and R^{T1} moieties are monovalent hydrocarbon groups;
the groups contain at least one group represented by —Z-(Q)n or a group represented by -A-(R^{D2}₂SiO)ₑ₁R^{D2}₂Si—Z¹-(Q)n in the molecule;
a1 to d1 are respectively 0 or positive numbers, and a1+b1+c1+d1 is a number within the range of 2 to 500; and the number of silicon atoms in the molecule is within the range of 2 to 1,000).
[5] The surface treatment agent for an optical material according to any one of [1] to [4], wherein the functional group (Q) bonded to silicon atoms directly or via a functional group with a valency of (n+1) (where n is a number equal to 1 or greater) in the organic silicon compound is a carboxyl group, an aldehyde group, a phosphoric acid group, a thiol group, a sulfo group, an alcoholic hydroxyl group, a phenolic hydroxyl group, an amino group, an ester group, an amide group, a polyoxyalkylene group, a silicon atom-containing hydrolyzable group represented by —SiR⁵_{f}X_{3-f} (wherein R⁵ is an alkyl group or an aryl group, X is a hydrolyzable group selected from an alkoxy group, an aryloxy group, an alkenoxy group, an acyloxy group, a ketoxymate group, and a halogen atom, and f is a number from 0 to 2), or a metal salt derivative thereof.
[6] The surface treatment agent for an optical material according to any one of [1] to [5], wherein the functional group bonded to silicon atoms via a functional group with a valency of (n+1) (where n is a number equal to 1 or greater) in the organic silicon compound is a group selected from a carboxyl group, an alcoholic hydroxyl group, a polyoxyalkylene group, and a silicon atom-containing hydrolyzable group represented by —SiR⁵_{f}X_{3-f} (wherein R⁵ is an alkyl group or an aryl group, X is a hydrolyzable group selected from an alkoxy group, an alkenoxy group, an aryloxy group, an acyloxy group, a ketoxymate group, and a halogen atom, and f is a number from 0 to 2).
[7] The surface treatment agent for an optical material according to any one of [1] to [6], wherein the functional group bonded to silicon atoms via a functional group with a valency of (n+1) (where n is a number equal to 1 or greater) in the organic silicon compound is a carboxyl group or a silicon atom-containing hydrolyzable group represented by —SiR⁵_{f}X_{3-f} bonded to silicon atoms via a divalent hydrocarbon group (wherein R⁵ is an alkyl group or an aryl group, X is a hydrolyzable group selected from an alkoxy group, an aryloxy group, an acyloxy group, a ketoxymate group, and a halogen atom, and f is a number from 0 to 2).
[8] The surface treatment agent for an optical material according to any one of [1] to [7], wherein the number of silicon atoms in the organic silicon compound is within a range of 2 to 500, and the functional group with a valency of (n+1) or the divalent functional group is a straight-chain or branched-chain alkylene group having from 2 to 20 carbon atoms.
[9] The surface treatment agent for an optical material according to any one of [1] to [8], for use on one or more optical fine members selected from fluorescent microparticles, metal oxide microparticles, metal microparticles, nanocrystal structures, and quantum dots or members in which part or entire surface of these members is covered by a silica layer.
[10] An optical material comprising a member which is surface-treated by the surface treatment agent for an optical material described in any one of [1] to [9].
[11] The optical material according to [10], wherein the member is a microparticulate member.
[12] A production method for an optical material in which a member is a microparticulate member, wherein the surface treatment agent for an optical member described in any one of [1] to [9] is used in at least one production step selected from a liquid-phase method, a solid-phase method, and a post-treatment method.
[13] The optical material according to [10] or [11] comprising: (A) at least one optical fine member selected from fluorescent microparticles, metal oxide microparticles, metal microparticles, nanocrystal structures, and quantum dots or members in which part or entire surface of these members is covered by a silica layer;
(B) the surface treatment agent for an optical material described in any one of claims 1 to 9; and
(C) a curable resin composition;
wherein the component (A) microparticles are dispersed in the component (C) curable resin composition after being surface-treated by the component (B) surface treatment agent for an optical material.
[14] The optical material according to [13], wherein the curable resin composition (C) is a hydrosilylation reaction-curable silicone composition.
[15] The optical material according to [13], wherein the curable resin composition (C) is a condensation reaction-curable silicone composition.
[16] The optical material according to any one of [13] to [15], further comprising (D) a fluorescent substance.
[17] The optical material according to any one of [10], [11], or [13] to [16], which is an optical material for an optical semiconductor.

### Advantageous Effects of Invention

With the present invention, it is possible to provide a novel surface treatment agent for an optical material. More specifically, it is possible to provide a surface treatment agent for an optical material consisting of an organic silicon compound which has excellent thermal stability and affinity with other curable resins and which can hydrophobically modify the surface of an optical fine member as necessary, for example, and can, in particular, dramatically modify the fine dispersibility and dispersion stability in hydrophobic resins. In addition, with the present invention, it is possible to provide an optical material containing a member which is surface-treated by this surface treatment agent for an optical material.

### BRIEF DESCRIPTION OF THE DRAWING

FIG. 1 is a cross-sectional view of a surface-mounted LED serving as an example of the optical semiconductor element of the present invention.

### DESCRIPTION OF EMBODIMENTS

The surface treatment agent for an optical material of the present invention contains an organic silicon compound having a specific functional group bonded to silicon atoms in the molecule and having at least one structure in the molecule in which other siloxane units bond to the silicon atoms. The specific functional group bonding to silicon atoms is a site which interacts with the surface of the optical material directly or after hydrolyzation, and other siloxane units bonding to the silicon atoms can further bond to other silicon atoms or other functional groups via divalent functional groups such as siloxane bonds (Si—O—Si) or silalkylene bonds so as to impart the organic silicon compound of the present invention with characteristics originating from a silicon polymer such as hydrophobicity. Since these functionally different sites are present in the same molecule, the organic silicon compound of the present invention can be used as a surface treatment agent for an optical material. Further, since the organic silicon compound of the present invention uses as a base a silicon polymer consisting of siloxane bonds (Si—O—Si), silalkylene bonds, or the like, the compound has excellent thermal stability (=heat resistance), which yields the advantage that it is unlikely to be susceptible to problems such as yellowing or discoloration of a surface-treated optical material or an optical device or the like produced by compounding the same. In addition, the compound has excellent affinity with other curable resins and silicone-based resins in particular, which has the advantage that the compound can be added in relatively large quantities with excellent compounding stability.

More specifically, the organic silicon compound of the present invention is an organic silicon compound having a functional group selected from a highly polar functional group, a hydroxyl group-containing group, a silicon atom-containing hydrolyzable group, or metal salt derivatives thereof bonded to silicon atoms directly or via a functional group with a valency of (n+1) (n is a number equal to 1 or greater) and

having at least one structure in the molecule in which the silicon atoms are bonded to any siloxane unit represented by R¹₃SiO_{1/2}, R¹₂SiO_{2/2}, R¹SiO_{3/2}, and SiO_{4/2} (wherein R¹ is a substituted or unsubstituted monovalent hydrocarbon group, a hydrogen atom, a halogen atom, a hydroxyl group, an alkoxy group, or a functional group selected from a highly polar functional group, a hydroxyl group-containing group, a silicon atom-containing hydrolyzable group, or metal salt derivatives thereof bonded to silicon atoms via a functional group with a valency of (n+1)).

A first feature of the organic silicon compound of the present invention is that the organic silicon compound has a functional group selected from a highly polar functional group, a hydroxyl group-containing group, a silicon atom-containing hydrolyzable group, or metal salt derivatives thereof bonded to silicon atoms directly or via a functional group with a valency of (n+1) (n is a number equal to 1 or greater). This functional group interacts with the surface of the optical material, which makes it possible to modify the characteristics of the surface by aligning, modifying, or forming a bond between the organic silicon compound of the present invention and the optical material surface. This interaction with the surface is an interaction or bond reaction with the material surface caused by the polarity of the functional group, the formation of hydrogen bonds caused by terminal hydroxyl groups, or a bond reaction with the material surface caused by a hydrolyzable functional group, and these interactions may be applied during or after the formation of the target optical material. In particular, at the time of the treatment of an optical material with high surface hydrophilicity in the untreated state, the interaction between the material surface and these functional groups is strong, which has the advantage that an excellent surface-modifying effect can be realized even when a small amount is used.

These functional groups bond to silicon atoms directly or via functional groups with a valency of (n+1) (n is a number equal to 1 or greater), but with the exception of cases in which the functional groups are hydroxyl groups (silanol groups), the functional groups preferably bond to silicon atoms via functional groups with a valency of (n+1) from the perspective of the surface-modifying effect. A functional group with a valency of (n+1) may be a linkage group with a valency of 2 or higher and is preferably a hydrocarbon group with a valency of 2 or higher which may contain hetero atoms (N, Si, O, P, S, or the like). A functional group with a valency of (n+1) may also be a linkage group with a valency of 3 or higher, and a structure in which two or more types of the same or different functional groups selected from highly polar functional groups, hydroxyl group-containing groups, silicon atom-containing hydrolyzable groups, or metal salt derivatives thereof are bonded to the linkage groups (for example, a highly polar functional group having a structure in which two carboxyl groups are bonded via trivalent functional groups) is included in the scope of the present invention.

More specifically, the functional group with a valency of (n+1) is a straight-chain or branched alkylene group which may contain hetero atoms selected from nitrogen, oxygen, phosphorus, and sulfur, an arylene group with a valency of 2 or higher, an alkenylene group with a valency of 2 or higher, an alkynylene group with a valency of 2 or higher, (poly)siloxane units, silalkylene units, or the like and is preferably a hydrocarbon group with a valency of 2 or higher to which a functional group (Q) is bonded in the alkylene portion or a portion other than the alkylene portion, the functional group (Q) being selected from a silicon atom or a highly polar functional group, a hydroxyl group-containing group, a silicon atom-containing hydrolyzable group, or metal salt derivatives thereof. The functional group with a valency of (n+1) is preferably a functional group with a valency of 2 to 4 and is particularly preferably a divalent functional group.

The functional group (Q) bonded to silicon atoms directly or via this functional group with a valency of (n+1) (n is a number equal to 1 or greater) includes a functional group (Q) bonded to the alkylene portion, for example, and is represented by the following structural formulas. The structure may be a halogenated alkylene structure in which some of the hydrogen atoms of the alkylene portion in the formulas are substituted with halogen atoms such as fluorine, and the structure of the alkylene portion may be a straight-chain or a branched-chain structure.

-Q

—CᵣH₂ᵣ₋ₜ₁—Cₛ₁H₍₂ₛ₁₊₁₋ₙ₎Qₙ

—CᵣH₂ᵣ-{T-Cₛ₂H₍₂ₛ₂₋ₙ₁₎Qₙ}ₜ₂-T-Cₛ₃H₍₂ₛ₃₊₁₋ₙ₂₎Qₙ₂

—CᵣH₂ᵣ-{T-Cₛ₂H₍₂ₛ₂₋ₙ₃₎Qₙ₃}ₜ₃-T-Cₛ₃H₂ₛ₃₊₁

—CᵣH₂ᵣ{T-Cₛ₂H₍₂ₛ₂₋ₙ₄₎Qₙ₄}ₜ₄-T-Q

[wherein Q is synonymous with that described above;
r is a number within the range of 1 to 20;
s1 is a number within the range of 1 to 20;
s2 is a number within the range of 0 to 20;
s3 is a number within the range of 1 to 20;
n is the same number as described above;
t1, t2, or t4 is a number equal to 0 or greater; and
t3 is a number equal to 1 or greater.
However, (n1×t2+n2), (n3×t4), and (n4×t4+1) are respectively numbers that satisfy n; and the T moieties are each independently single bonds, alkenylene groups having from 2 to 20 carbon atoms, arylene groups having from 6 to 22 carbon atoms, or divalent linkage groups represented by —CO—, —O—C(═O)—, —C(═O)—O—, —C(═O)—NH—, —O—, —S—, —O—P—, —NH—, —SiR⁹₂—, and —[SiR⁹₂O]₁₅— (wherein the R9 moieties are each independently alkyl groups or aryl groups, and t5 is a number within the range of 1 to 100).]

The functional group with a valency of (n+1) is particularly preferably a divalent linkage group,

examples of which include a divalent hydrocarbon group (—Z¹—) or
a group represented by -A-(R^{D2}₂SiO)ₑ₁R^{D2}₂Si—Z¹—.
Here, A and Z¹ are each independently divalent hydrocarbon groups and are preferably alkylene groups having from 2 to 20 carbon atoms.
R^{D2} is an alkyl group or an aryl group and is preferably a methyl group or a phenyl group.
e1 is a number in the range from 1 to 50, preferably from 1 to 10, and particularly preferably 1.

Q described above is a functional group selected from a highly polar functional group, a hydroxyl group-containing group, a silicon-bonded hydrolyzable group, or metal salt derivatives thereof.

A highly polar functional group is specifically a polar functional group containing hetero atoms (O, S, N, P, or the like), and the functional group interacts with the substrate surface of the optical material or reactive functional groups (including hydrophilic groups) present on the substrate surface so as to bond or align the organic silicon compound with the substrate surface, which contributes to surface modification. Examples of such highly polar functional groups include functional groups having polyoxyalkylene groups, cyano groups, amino groups, imino groups, quaternary ammonium groups, carboxyl groups, ester groups, acyl groups, carbonyl groups, thiol groups, thioether groups, sulfone groups, hydrogen sulfate groups, sulfonyl groups, aldehyde groups, epoxy groups, amide groups, urea groups, isocyanate groups, phosphoric acid groups, oxyphosphoric acid groups, and carboxylic anhydride groups, or the like. These highly polar functional groups are preferably functional groups derived from amines, carboxylic acids, esters, amides, amino acids, peptides, organic phosphorus compounds, sulfonic acids, thiocarboxylic acids, aldehydes, epoxy compounds, isocyanate compounds, or carboxylic acid anhydrides.

A hydroxyl group-containing group is a hydrophilic functional group having a silanol group, an alcoholic hydroxyl group, a phenolic hydroxyl group, or a polyether hydroxyl group which typically induces dehydrative condensation or forms one or more hydrogen bonds with the optical material surface, which is an inorganic substance (M) so as to bond or align the organic silicon compound with the substrate surface, thereby contributing to the modification of the surface. Specific examples include silanol groups bonded to silicon atoms, monovalent or polyvalent alcoholic hydroxyl groups, sugar alcoholic hydroxyl groups, phenolic hydroxyl groups, and polyoxyalkylene groups having OH groups at the terminals. These are preferably functional groups derived from hydroxysilanes, monovalent or polyvalent alcohols, phenols, polyether compounds, (poly)glycerin compounds, (poly)glycidyl ether compounds, or hydrophilic sugars.

A silicon atom-containing hydrolyzable group is a functional group having at least one hydrolyzable group bonded to silicon atoms and is not particularly limited as long as the group is a silyl group having at least monovalent hydrolyzable atoms directly coupled with silicon atoms (atoms producing silanol groups by reacting with water) or monovalent hydrolyzable groups directly coupled with silicon atoms (groups producing silanol groups by reacting with water). Such a silicon atom-containing hydrolyzable group generates a silanol group when hydrolyzed, and this silanol group is dehydrative condensated with the optical material surface, which is typically an inorganic substance (M), so as to form a chemical bond consisting of Si—O-M (optical material surface). One or two or more of these silicon atom-containing hydrolyzable groups may be present in the organic silicon compound of the present invention, and when two or more groups are present, the groups may be of the same or different types.

A preferable example of a silicon atom-containing hydrolyzable group is a silicon atom-containing hydrolyzable group represented by —SiR⁵_{f}X_{3-f}. In the formula, R⁵ is an alkyl group or an aryl group, X is a hydrolyzable group selected from alkoxy groups, aryloxy groups, alkenoxy groups, acyloxy groups, oxime groups, amino groups, amide groups, mercapto groups, aminoxy groups, and halogen atoms, and f is a number from 0 to 2. More specifically, X is a hydrolyzable group selected from alkoxy groups such as methoxy groups, ethoxy groups, and isopropoxy groups; alkenoxy groups such as isopropenoxy groups; acyloxy groups such as acetoxy groups and benzoyloxy groups; oxime groups such as methyl ethyl ketoxime groups; amino groups such as dimethylamino groups and diethylamino groups; amide groups such as N-ethylacetamide groups; mercapto groups; aminoxy groups, and halogen atoms, and alkoxy groups having from 1 to 4 carbon atoms, (iso)propenoxy groups, or chlorine are preferable. In addition, R⁵ is preferably a methyl group or a phenyl group. Specific examples of these silicon atom-containing hydrolyzable groups include but are not limited to trichlorosilyl groups, trimethoxysilyl groups, triethoxysilyl groups, methyldimethoxysilyl groups, and dimethylmethoxysilyl groups.

Metal salt derivatives of the highly polar functional groups, hydroxyl group-containing groups, and silicon atom-containing hydrolyzable groups described above are functional groups in which some alcoholic hydroxyl groups, organic acid groups such as carboxyl groups, or —OH groups such as silanol groups, phosphoric acid groups, or sulfonic acid groups form a salt structure with a metal. Particularly preferable examples include alkali metal salts such as sodium, alkali earth metal salts such as magnesium, and aluminum salts. In these metal salt derivatives, the —O⁻ portion in the functional group electrostatically interacts with the surface of the optical material or forms hydrogen bonds so as to bond or align the organic silicon compound with the substrate surface, which contributes to the modification of the surface.

The functional group (Q) is particularly preferably a group selected from carboxyl groups, aldehyde groups, phosphoric acid groups, thiol groups, sulfo groups, alcoholic hydroxyl groups, phenolic hydroxyl groups, amino groups, ester groups, amide groups, polyoxyalkylene groups, and silicon atom-containing hydrolyzable groups represented by —SiR⁵_{f}X_{3-f} (wherein R⁵ is an alkyl group or an aryl group, X is a hydrolyzable group selected from an alkoxy group, an aryloxy group, an alkenoxy group, an acyloxy group, a ketoxymate group, and a halogen atom, and f is a number from 0 to 2) or metal salt derivatives thereof. In particular, when the organic silicon compound of the present invention is used to post-treat the surface of one or more optical fine members selected from fluorescent microparticles, metal oxide microparticles, metal microparticles, nanocrystalline structures, and quantum dots with the objective of improving the dispersibility thereof, carboxyl groups, monovalent or polyvalent alcoholic hydroxyl groups, polyoxyalkylene groups, and silicon atom-containing hydrolyzable groups represented by —SiR⁵_{f}X_{3-f} are preferably used.

A second feature of the organic silicon compound of the present invention is that silicon atoms having functional groups (Q) bonded directly or via functional groups with a valency of (n+1) (n is a number equal to 1 or greater) are bonded to a siloxane unit represented by one of R¹₃SiO_{1/2}, R¹₂SiO_{2/2}, R¹SiO_{3/2}, and SiO_{4/2}. In this siloxane portion, other siloxane units bonding to the silicon atoms may further bond to other silicon atoms or other functional groups via divalent functional groups such as siloxane bonds (Si—O—Si) or silalkylene bonds, which makes it possible to impart the organic silicon compound of the present invention with characteristics such as hydrophobicity originating from a silicon polymer or the like. More specifically, the organic silicon compound of the present invention interacts with the surface of the optical material via a functional group (Q) selected from the aforementioned highly polar functional groups, hydroxyl group-containing groups, silicon atom-containing hydrolyzable groups, or metal salt derivatives thereof, and the properties of the surface such as the hydrophobicity, fine dispersibility, and dispersion stability are modified by the characteristics originating from the silicon polymer. In addition, the affinity between the organic silicon compound and hydrophobic materials is dramatically improved by this portion, which makes it possible to add the compound to other substrates in large quantities in accordance with applications of the optical materials. Further, since a structure consisting of siloxane bonds (Si—O—Si), silalkylene bonds, or the like has excellent thermal stability, problems such as the yellowing or discoloration of optical materials or the like treated using the organic silicon compound or an optical device containing the optical materials are unlikely to arise, which yields the advantage that the heat resistance is improved.

In the formula, R¹ is a substituted or unsubstituted monovalent hydrocarbon group, a hydrogen atom, a halogen atom, a hydroxyl group, an alkoxy group, or a functional group selected from a highly polar functional group, a hydroxyl group-containing group, a silicon atom-containing hydrolyzable group, or metal salt derivatives thereof bonded to silicon atoms via a functional group with a valency of (n+1). Here, the substituted or unsubstituted monovalent hydrocarbon groups are preferably independently an alkyl group having from 1 to 10 carbon atoms, an alkenyl group having from 2 to 10 carbon atoms, or an aryl group or an aralkyl group having from 6 to 22 carbon atoms, and examples include straight-chain, branched, or cyclic alkyl groups such as methyl, ethyl, n-propyl, i-propyl, n-butyl, i-butyl, s-butyl, pentyl, neopentyl, cyclopentyl, and hexyl; alkenyl groups such as vinyl groups, propenyl groups, butyl groups, pentyl groups, and hexenyl groups; phenyl groups, and naphthyl groups. R¹ is industrially preferably a hydrogen atom, a methyl group, a vinyl group, a hexenyl group, a phenyl group, or a naphthyl group. In addition, the hydrogen atoms bonded to the carbon atoms of these groups of R¹ may be at least partially substituted with halogen atoms such as fluorine. Further, the functional groups selected from highly polar functional groups, hydroxyl group-containing groups, silicon atom-containing hydrolyzable groups, and metal salt derivatives thereof bonded to the silicon atoms via functional groups with a valency of (n+1) are the same groups as those described above.

The organic silicon compound of the present invention has at least two silicon atoms in the molecule as a result of having the structure described above, but from the perspective of the modification of the surface of the optical material, it is preferable for the organic silicon compound of the present invention to have a constant number of hydrophobic siloxane units in the molecule. Therefore, the surface treatment agent differs from known silane coupling agents with regard to its structure and differs from surface treatment agents consisting of known organically modified silicones with regard to the specific application of modifying the surface of an optical material and the designed molecular structure.

It is preferable for the organic silicon compound of the present invention to have from 2 to 1000 silicon atoms in the molecule. However, when the functional groups (Q) are silicon atom-containing hydrolyzable groups, it is preferable to have from 2 to 1000 silicon atoms in the molecule, excluding the silicon atoms in the functional groups (Q). Here, the number of silicon atoms in the organic silicon compound excluding the silicon atoms in the functional groups (Q) is more preferably from 2 to 500 atoms, the range of 2 to 400 atoms is more preferable, the range of 2 to 200 atoms is particularly preferable, and the range of 2 to 100 is the most preferable. In particular, when the organic silicon compound of the present invention is used to post-treat the surface of one or more optical fine members selected from fluorescent microparticles, metal oxide microparticles, metal microparticles, nanocrystal structures, and quantum dots or members having a surface which is partially or completely covered by a silica layer with the objective of improving the dispersibility or the like thereof, the number of silicon atoms in the organic silicon compound of the present invention is more preferably from 3 to 500 and even more preferably from 5 to 200, and the range of 7 to 100 atoms is particularly preferable. Further, the surface treatment agent of the present invention may also combine an organic silicon compound with a relatively large number of silicon atoms and an organic silicon compound with a relatively small number of silicon atoms in accordance with the type, size, treatment method, and the like of the optical material used for treatment.

From the perspective of modifying the surface of the optical material, it is preferable for at least 50 mol % of all of the monovalent functional groups bonded to silicon atoms to be monovalent hydrocarbon groups, and it is particularly preferable for at least 75 mol % of all of the monovalent functional groups bonded to silicon atoms to be monovalent hydrocarbon groups. Further, it is preferable for the number of silicon atoms having the functional groups (Q) bonded directly or via functional groups with a valency of (n+1) (n is a number equal to 1 or greater) in the organic silicon compound of the present invention (excluding the silicon atoms in the functional groups (Q)) to be a number no greater than ⅓ the number of all of the silicon atoms in the molecule (excluding the silicon atoms in the functional groups (Q). From the perspective of modifying the surface of the optical material, the number is preferably at most ⅕, more preferably at most 1/10, and particularly preferably at most 1/20 the number of all of the silicon atoms in the molecule. At this time, it is particularly preferable for at least 90 mol % of all of the monovalent functional groups bonding to silicon atoms to be monovalent hydrocarbon groups selected from methyl groups, vinyl groups, hexenyl groups, phenyl groups, and naphthyl groups.

Such an organic silicon compound may employ a straight-chain, branched-chain, reticulated (network), or ring-shaped molecular structure and is represented by the following average structural formula, including cases in which the compound contains bonds mediated by divalent functional groups between Si moieties of siloxane bonds or silalkylene bonds in the molecule.

(R^{M}₃SiO_{1/2})ₐ(R^{D}₂SiO_{2/2})_{b}(R^{T}SiO_{3/2})_{c}(SiO_{4/2})_{d}

In the formula, R^{M}, R^{D}, and R^{T} are each independently monovalent hydrocarbon groups, hydrogen atoms, hydroxyl groups, alkoxy groups, groups having functional groups (Q) selected from highly polar functional groups, hydroxyl group-containing groups, silicon atom-containing hydrolyzable groups, or metal salt derivatives thereof bonded to silicon atoms directly or via functional groups with a valency of (n+1) represented by —Z-(Q)n described above, or divalent functional groups bonded to the Si atoms of other siloxane units. Here, the monovalent hydrocarbon groups are synonymous with those described above, and examples of the divalent functional groups bonded to the Si atoms of other siloxane units include but are not limited to alkylene groups having from 2 to 20 carbon atoms and aralkylene groups having from 8 to 22 carbon atoms. From an industrial perspective and the perspective of modifying the surface of the optical material, it is preferable for at least 50 mol % of all of the R^{M}, R^{D}, and R^{T} moieties to be monovalent hydrocarbon groups, and it is particularly preferable for at least 75 mol % to be monovalent hydrocarbon groups.

At least one of all of the R^{M}, R^{D}, and R^{T} moieties is a group having a functional group (Q) selected from highly polar functional groups, hydroxyl group-containing groups, silicon atom-containing hydrolyzable groups, or metal salt derivatives thereof bonded to silicon atoms directly or via functional groups with a valency of (n+1), wherein n is a number equal to 1 or greater, a to d are respectively 0 or positive numbers, and a+b+c+d is a number within the range of 2 to 1,000. Here, a+b+c+d is preferably from 2 to 500 and more preferably from 2 to 100. In addition, when used to post-treat the surface of an optical fine member with the objective of improving the dispersibility thereof, a+b+c+d is more preferably from 3 to 500, even more preferably within the range of 5 to 200, and particularly preferably within the range of 7 to 100. At this time, the number of silicon atoms having the functional groups (Q) in the average structural formula described above (x, excluding the silicon atoms in the functional groups (Q)) is preferably a number equal to at most ⅓ of a+b+c+d. From the perspective of modifying the surface of the optical material, the number is more preferably at most ⅕, even more preferably at most 1/10, and particularly preferably at most 1/20 of a+b+c+d.

The organic silicon compound of the present invention particularly preferably has an essentially hydrophobic a main chain siloxane structure consisting of straight-chain or branched-chain siloxane bonds or silalkylene bonds and has functional groups (Q) selected from highly polar functional groups, hydroxyl group-containing groups, silicon atom-containing hydrolyzable groups, or metal salt derivatives thereof bonded to silicon atoms of the side chains (including structures that are branched via silalkylene bonds or the like) or terminals directly or via functional groups with a valency of (n+1). At this time, with the objective of imparting advanced hydrophobicity or the like, a molecular design may be—and is preferably—employed so that the compound has a highly branched siloxane dendron structure or a siloxane macromonomer structure having a constant chain length. These hydrophobic siloxane structures and main chain siloxane structures are preferably bonded by divalent hydrocarbon groups such as silalkylenes.

Such an organic silicon compound is represented by the following average structural formula.

(R^{M1}₃SiO_{1/2})ₐ₁(R^{D1}₂SiO_{2/2})_{b1}(R^{T1}SiO_{3/2})_{c1}(SiO_{4/2})_{d1}

In the formula, R^{M1}, R^{D1}, and R^{T1} are each independently groups selected from: monovalent hydrocarbon groups, hydrogen atoms, hydroxyl groups, alkoxy groups, groups having functional group (Q) selected from highly polar functional groups, hydroxyl group-containing groups, silicon atom-containing hydrolyzable groups, or metal salt derivatives thereof bonded to silicon atoms via divalent functional groups (Z¹) represented by —Z¹-Q; groups represented by -A-(R^{D2}₂SiO)ₑ₁R^{D2}₂Si—Z¹-Q (wherein A is a divalent hydrocarbon group,

R^{D2} is an alkyl group or a phenyl group, e1 is a number within the range of 1 to 50, and Z¹ and Q are synonymous with those described above);
groups represented by -A-(R^{D2}₂SiO)ₑ₁SiR^{M2}₃ (wherein A and R^{D2} are synonymous with those described above, R^{M2} is an alkyl group or a phenyl group, and e1 is the same number as described above); or
groups represented by —O—Si(R^{D3})₂—X¹ (wherein R^{D3} is an alkyl group having from 1 to 6 carbon atoms or a phenyl group, and X¹ is a silylalkyl group represented by the following general formula (2) when i=1):

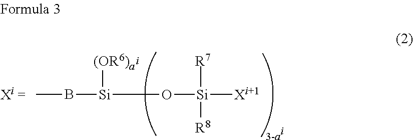

(wherein R⁶ is a hydrogen atom or an alkyl group having from 1 to 6 carbon atoms or phenyl group, and R⁷ or R⁶ is a hydrogen atom or an alkyl group having from 1 to 6 carbon atoms or phenyl group; B is a straight-chain or branched-chain alkylene group represented by CᵣH₂ᵣ; r is an integer from 2 to 20;
i represents the hierarchies of a silylalkyl group represented by Xⁱ, which is an integer from 1 to c when the number of hierarchies is c; the number of hierarchies c is an integer from 1 to 10; aⁱ is an integer from 0 to 2 when i is 1 and is a number less than 3 when i is 2 or greater; X¹⁺¹ is a silylalkyl group when i is less than c and is a methyl group (—CH₃) when i=c).
Here, the monovalent hydrocarbon groups are synonymous with those described above, and examples of the divalent hydrocarbon groups serving as A include but are not limited to alkylene groups having from 2 to 20 carbon atoms and aralkylene groups having from 8 to 22 carbon atoms. In addition, the silylalkyl group represented by X¹ is known as a carbosiloxane dendrimer structure, an example of which is a group using a polysiloxane structure as a skeleton and having a highly branched structure in which siloxane bonds and silalkylene bonds are arranged alternately, as described in Japanese Unexamined Patent Application Publication No. 2001-213885.

It is preferable for at least 50 mol % of all of the R^{M1}, R^{D1}, and R^{T1} moieties to be monovalent hydrocarbon groups, and at least one group represented by —Z¹-(Q)n or a group represented by -A-^{D2}₂SiO)ₑ₁R^{D2}₂Si—Z¹-(Q)n is contained in the molecule. a1 to d2 are respectively 0 or positive numbers, and a1+b1+c1+d1 is a number within the range from 2 to 500. In addition, the number of silicon atoms in the molecule, including siloxane portions that are branched via other divalent hydrocarbon groups, is within the range of 2 to 1,000. In particular, when the organic silicon compound of the present invention is used to post-treat the surface of one or more optical fine members selected from fluorescent microparticles, metal oxide microparticles, metal microparticles, nanocrystal structures, and quantum dots or members having a surface which is partially or completely covered by a silica layer with the objective of improving the dispersibility or the like thereof, the number of silicon atoms in the organic silicon compound of the present invention is such that a1+b1+c1+d1 is a number within the range of 3 to 500, and the number of silicon atoms in the organic silicon compound is preferably at most 500 atoms. Further, it is more preferable for a1+b1+c1+d1 to be a number within the range of 5 to 200 and for the number of silicon atoms in the organic silicon compound to be a number within the range of at most 200 atoms. It is most preferable for a1+b1+c1+d1 to be a number within the range of 7 to 100 and for the number of silicon atoms in the organic silicon compound to be a number within the range of at most 100 atoms. At this time, the number of silicon atoms having the functional groups (Q) in the average structural formula described above (x, excluding the silicon atoms in the functional groups (Q)) is preferably a number equal to at most ⅓ of the number of silicon atoms in the organic silicon compound. From the perspective of modifying the surface of the optical material, the number is more preferably at most ⅕, even more preferably at most 1/10, and particularly preferably at most 1/20 of the number of silicon atoms in the organic silicon compound.

The organic silicon compound of the present invention can be used as a surface treatment agent for a transparent optical material having a high refractive index used in a sealant for an optical semiconductor or an optical lens. In this case, the refractive index of the organic silicon compound at 25° C. is preferably at least 1.45 and is particularly preferably at least 1.50. An organic silicon compound with such a high refractive index can be achieved by designing the compound so that at least 30 mol % and preferably at least 40 mol % of all of the silicon-bonded functional groups in the molecule are selected from phenyl groups, condensed polycyclic aromatic groups, and groups containing condensed polycyclic aromatic groups.

The organic silicon compound of the present invention can be and is preferably designed so as to contain in the molecule a functional group which is reactive with hydrophobic resins to which the optical material is added for the purpose of further improving the fine dispersibility, dispersion stability, and the like of the surface-treated optical material in a curable resin. For example, the compound may have condensation reactive functional groups or hydrosilylation reactive functional groups in the molecule for the purpose of improving the compounding stability in a silicone resin which is cured by a condensation reaction or a hydrosilylation reaction. The numbers and types of these functional groups in the molecule are not particularly limited, but the compound preferably has 1 to 3 groups in the molecule, and examples of condensation reactive functional groups include silanol groups and silicon-bonded alkoxy groups. Also, examples of hydrosilylation-reactive functional groups include silicon-bonded hydrogen atoms, alkenyl groups, and acyloxy groups.

In particular, when the organic silicon compound of the present invention has one or more condensation reactive functional groups or hydrosilylation reactive functional groups in the molecule, the compound can be used not only as a surface treatment agent, but also as all or part of the primary agent of a curable resin composition. Specifically, the entire composition may be cured following a method of adding the aforementioned silicon compound having at least one condensation-reactive functional group or hydrosilylation-reactive functional group in the molecule as the curable silicone resin composition, a reactive silicone serving as a cross-linking agent, a substrate, and a curing reaction catalyst and treating the surface of the optical material in-situ (integral blending method). In particular, since the organic silicon compound of the present invention has excellent compounding stability with respect to silicone materials, the dispersibility and thermal stability of the substrate in the cured product are particularly favorable after the curing reaction when the material has a high refractive index of at least 1.50, which yields the advantage that the entire cured product is uniform and has a high refractive index.

For example, preparing a curable silicone resin composition containing a substrate surface-treated by the organic silicon compound of the present invention by uniformly mixing a substrate, the organic silicon compound described above having at least one alkenyl group or acyloxy group in the molecule, an organopolysiloxane having at least two silicon-bonded hydrogen atoms in each molecule, and a hydrosilylation reaction catalyst and curing the composition by heating or the like is included in the preferred embodiments of the present invention.

Such an organic silicon compound of the present invention has an essentially hydrophobic a main chain siloxane structure consisting of straight-chain or branched-chain siloxane bonds or silalkylene bonds represented by the following structural formulas (3-1) to (3-5), examples of which include organic silico compounds having functional groups (Q) selected from highly polar functional groups, hydroxyl group-containing groups, silicon atom-containing hydrolyzable groups, or metal salt derivatives thereof bonded to silicon atoms of the side chains (including structures that are branched via silalkylene bonds or the like) or terminals directly or via functional groups with a valency of (n+1).

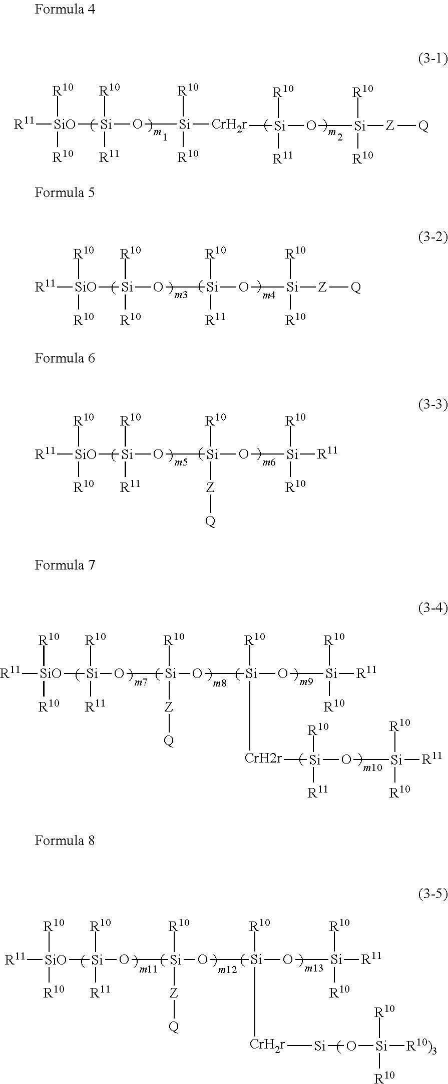

In the formula, —Z-Q is synonymous with that described above; the R¹⁰ moieties are each independently methyl groups, phenyl groups, or naphthyl groups; and the R¹¹ moieties are each independently monovalent functional groups selected from hydrogen atoms, alkyl groups having from 1 to 20 carbon atoms, alkenyl groups having from 2 to 22 carbon atoms, phenyl groups, and naphthyl groups, and groups represented by —Z-Q.

In formula (3-1), m1 and m2 are respectively numbers equal to 1 or greater, wherein m1+m2 is preferably a number within the range of 2 to 400, and m1 and m2 are particularly preferably numbers within the ranges of 2 to 200 and from 1 to 100, respectively. In formula (3-1), r is a number within the range of 1 to 20 and is preferably a number within the range of 2 to 12. With the objective of improving the compounding stability in a hydrosilylation reaction-curable silicone resin, it is particularly preferable for at least one of the functional groups represented by R¹¹ to be an alkenyl group having from 2 to 22 carbon atoms or a hydrogen atom. Further, with the objective of increasing the refractive index of the organic silicon compound, it is preferable for at least 40 mol % of all of the R¹⁰ and R¹¹ moieties to be phenyl groups or naphthyl groups. In addition, the number of silicon atoms to which the groups represented by —Z-Q are bonded is preferably a number equal to at most ⅓ the number of silicon atoms in the organic silicon compound represented by formula (3-1) (excluding the silicon atoms in the functional groups (Q)) and, from the perspective of modifying the surface of the optical material, is more preferably a number equal to at most ⅕ the number of silicon atoms in the organic silicon compound.

In formula (3-2), m3 and m4 are respectively numbers equal to 0 or greater, wherein m3+m4 is preferably a number within the range of 0 to 400, and m3 and m4 are particularly preferably numbers within the ranges of 2 to 300 and 0 to 100, respectively. With the objective of improving the compounding stability in a hydrosilylation reaction-curable silicone resin, it is particularly preferable for at least one of the functional groups represented by R¹¹ to be an alkenyl group having from 2 to 22 carbon atoms or a hydrogen atom. Further, with the objective of increasing the refractive index of the organic silicon compound, it is preferable for at least 40 mol % of all of the R¹⁰ and R¹¹ moieties to be phenyl groups or naphthyl groups. In addition, the number of silicon atoms to which the groups represented by —Z-Q are bonded is preferably a number equal to at most ⅓ the number of silicon atoms in the organic silicon compound represented by formula (3-2) (excluding the silicon atoms in the functional groups (Q)) and, from the perspective of modifying the surface of the optical material, is more preferably a number equal to at most ⅕ the number of silicon atoms in the organic silicon compound.

In formula (3-3), m5 is a number equal to 0 or greater, m6 is a number equal to 1 or greater, wherein m5+m6 is preferably a number within the range of 1 to 400, and m5 and m4 are particularly preferably numbers within the ranges of 0 to 300 and 1 to 10, respectively. With the objective of improving the compounding stability in a hydrosilylation reaction-curable silicone resin, it is particularly preferable for at least one of the functional groups represented by R¹¹ to be an alkenyl group having from 2 to 22 carbon atoms or a hydrogen atom. Further, with the objective of increasing the refractive index of the organic silicon compound, it is preferable for at least 40 mol % of all of the R¹⁰ and R¹¹ moieties to be phenyl groups or naphthyl groups. In addition, the number of silicon atoms to which the groups represented by —Z-Q are bonded is preferably a number equal to at most ⅓ the number of silicon atoms in the organic silicon compound represented by formula (3-3) (excluding the silicon atoms in the functional groups (Q)) and, from the perspective of modifying the surface of the optical material, is more preferably a number equal to at most ⅕ the number of silicon atoms in the organic silicon compound.

In formula (3-4), m7 is a number equal to 0 or greater, m8 and m9 are respectively numbers equal to 1 or greater, and m10 is a number within the range of 1 to 50. It is preferable for m7+m8+m9 to be a number within the range of 2 to 400. It is also preferable for m7 to be a number within the range of 2 to 200 and for m8 or m9 to respectively be a number within the range of 1 to 100. In formula (3-4), r is a number within the range of 1 to 20 and is preferably a number within the range of 2 to 12. In addition, with the objective of improving the compounding stability in a hydrosilylation reaction-curable silicone resin, it is particularly preferable for at least one of the functional groups represented by R¹¹ to be an alkenyl group having from 2 to 22 carbon atoms or a hydrogen atom. Further, with the objective of increasing the refractive index of the organic silicon compound, it is preferable for at least 40 mol % of all of the R¹⁰ and R¹¹ moieties to be phenyl groups or naphthyl groups. In addition, the number of silicon atoms to which the groups represented by —Z-Q are bonded is preferably a number equal to at most ⅓ the number of silicon atoms in the organic silicon compound represented by formula (3-4) (excluding the silicon atoms in the functional groups (Q)) and, from the perspective of modifying the surface of the optical material, is more preferably a number equal to at most ⅕ the number of silicon atoms in the organic silicon compound.

The structure represented by formula (3-5) has a carbosiloxane dendrimer structure in the molecule, wherein m11 is a number equal to 0 or greater, m12 is a number equal to 1 or greater, and m13 is a number equal to 1 or greater. It is preferable for m11+m12+m13 to be a number within the range of 2 to 400, and it is particularly preferable for m11 to be a number within the range of 2 to 200 and for m8 or m9 to respectively be a number within the range of 1 to 100. In formula (3-5), r is a number within the range of 1 to 20 and is preferably a number within the range of 2 to 12. In addition, with the objective of improving the compounding stability in a hydrosilylation reaction-curable silicone resin, it is particularly preferable for at least one of the functional groups represented by R¹¹ to be an alkenyl group having from 2 to 22 carbon atoms or a hydrogen atom. Further, with the objective of increasing the refractive index of the organic silicon compound, it is preferable for at least 40 mol % of all of the R¹⁰ and R¹¹ moieties to be phenyl groups or naphthyl groups. In addition, the number of silicon atoms to which the groups represented by —Z-Q are bonded is preferably a number equal to at most ⅓ the number of silicon atoms in the organic silicon compound represented by formula (3-5) (excluding the silicon atoms in the functional groups (Q)) and, from the perspective of modifying the surface of the optical material, is more preferably a number equal to at most ⅕ the number of silicon atoms in the organic silicon compound.

The production method of the organic silicon compound of the present invention is not particularly limited, but the compound can be obtained, for example, by reacting a siloxane raw material having a reactive group such as an alkenyl group, an amino group, a halogen atom, or a hydrogen atom in the molecule and an organic compound or an organic silicon compound having a group that is reactive with the functional groups (Q) described above in the presence of a catalyst. By adjusting the reaction ratio of the structure of the siloxane raw material and the compound having the functional groups (Q), it is possible to adjust the number of functional groups introduced into the molecule.

The surface treatment agent for an optical material of the present invention contains the organic silicon compound described above and particularly preferably contains at least 50 mass % of the organic silicon compound described above as the primary agent. On the other hand, the surface treatment agent for an optical material of the present invention may also be used after being diluted in a conventionally known solvent or the like, and examples of such a solvent include siloxane compounds which are liquid at room temperature; alcohols such as methanol, ethanol, and n-butanol; aromatic hydrocarbons such as toluene and xylene; aliphatic hydrocarbons such as hexane and decane; ethers such as diethyl ether tetrahydrofuran and dioxane; esters such as ethyl acetate and butyl acetate; ketones such as methyl ethyl ketone and methyl isobutyl ketone; amides such as dimethylformamide; halogenated hydrocarbons such as chloroform and carbon tetrachloride; methyl methacrylate, ethyl methacrylate, hydroxyethyl methacrylate, and ethyl acrylate.

In addition, other additives such as antioxidants, anti-aging agents, pigments, dyes, other organic silicon compounds, such as silane coupling agents or silylating agents, organic titanate compounds, organic aluminate compounds, organic tin compounds, waxes, fatty acids, fatty acid esters, fatty acid salts, or silanol condensation catalysts such as organic tin compounds may also be added to the surface treatment agent for an optical material of the present invention within a scope that does not depart from the purpose of the present invention. Examples of other surface treatment agents include silane compounds such as methyl(trimethoxy)silane, ethyl(trimethoxy)silane, hexyl(trimethoxy)silane, decyl(trimethoxy)silane, vinyl(trimethoxy)silane, 2-[(3,4)-epoxycyclohexyl]ethyl(trimethoxy)silane, 3-glycidoxypropyl(trimethoxy)silane, 3-methacryloxypropyl(trimethoxy)silane, 3-methacryloxypropyl(trimethoxy)silane, 3-acryloxypropyl(trimethoxy)silane, and 1-(trimethoxy)3,3,3-trimethylsiloxane. The present invention may also contain other reactive silicone compounds within a scope that does not inhibit the effect of the present invention.

The surface treatment agent for an optical material of the present invention is used in the surface treatment of an optical material and is particularly suitable for the surface treatment of optical material used in light-emitting semiconductors and illumination instruments and displays using the same. Such an optical material may be an optical element molded or assembled in advance or may be a raw material member of an optical element such as metal nanoparticles or a filler. In addition, surface treatment may be performed at a timing either before or after the molding of the optical element and may be an organic modifier for a microparticle surface in the synthesis process of a microparticulate member (for example, nanoparticles) or may be used in a post-treatment agent for a synthesized microparticulate member. It is particularly preferable to form an optical element such as a sealant, a lens, a reflector, a transparent adhesive layer, a fluorescent layer (including a remote phosphor member), or an optical semiconductor module after treating the raw material member in advance with the surface treatment agent for an optical material of the present invention. However, the surface treatment agent for an optical material of this application may also be used for the purpose of the surface modification (for example, the prevention of contamination due to hydrophobicity) of a performed optical element (the surface or the like of a lens or an optical semiconductor sealant layer).

The member that is preferably treated by the surface treatment agent for an optical material of the present invention is a raw material member of an optical element, and the surface treatment agent is particularly preferable for the surface treatment of an inorganic raw material member. In particular, the surface treatment agent for an optical material of the present invention is suitable as a surface treatment agent for an optical fine member and is suited to the surface treatment of a fine member having an average particle size or structural units (for example, crystal structural units or the like) of 1 mm (1,000 μm to 1 nm). Unless specified otherwise hereafter, “average particle size” will refer to the average particle size (cumulant average particle size) calculated from the signal strength when measured with a dynamic light scattering particle size distribution meter using a cumulant method as a correlation function calculation method.

In particular, the member that is preferably treated by the surface treatment agent for an optical material of the present invention is at least one optical fine member selected from fluorescent microparticles, metal oxide microparticles, metal microparticles, nanocrystal structures, and quantum dots, or members in which part or entire surface of these members is covered by a silica layer. These are well known as raw materials for light-emitting semiconductor devices or the like, and the surface treatment agent for an optical material of the present invention is suitable for the surface treatment of these fine members, but when used as a surface treatment agent for metal oxide microparticles with a particle size of 1 to 500 nm or particles having a surface which is partially or completely covered by a silica layer, in particular, it is possible to dramatically improve the fine dispersibility and dispersion stability in hydrophobic curable resins and in silicone resins, in particular, which yields the advantage that the functionality of the resulting curable resin can be improved. In addition, when an optical material treated by the surface treatment agent for an optical material of the present invention is used in an optical semiconductor element or the like, there is the advantage that the element will have excellent heat resistance and will be less susceptible to yellowing, discoloration, or the like.

Fluorescent microparticles are inorganic microparticles which emit fluorescent light of a longer wavelength than the wavelength of ultraviolet or visible excitation light when the excitation light is incident on the microparticles. In particular, it is preferable to use microparticles having an excitation band at a frequency of 300 to 500 nm and having a light-emission peak at a wavelength of 380 to 780 nm and, in particular, fluorescent microparticles which emit blue light (wavelength: 440 to 480 nm), green light (wavelength: 500 to 540 nm), yellow light (wavelength: 540 to 595 nm), and red light (wavelength: 600 to 700 nm). Examples of fluorescent microparticles that are typically available on the market include garnets such as YAG, other oxides, nitrides, oxynitrides, sulfides, oxysulfides, rare earth sulfides, or rare earth aluminate chlorides or halophosphate chlorides activated primarily by a lanthanoid element such as Ce represented by Y₃Al₅O₁₂:Ce, (Y, Gd)₃Al₅O₁₂:Ce, Y₃(Al, Ga)₅O₁₂:Ce, or the like. Specific examples of these fluorescent microparticles are, for example, the inorganic fluorescent microparticles disclosed in Japanese Unexamined Patent Application Publication No. 2012-052018.

The fluorescent microparticles treated using the surface treatment agent for an optical material of the present invention typically have an average particle size within the range of 0.1 to 300 μm and may be treated in the state of a mixture with a glass powder such as glass beads. Further, the surface treatment agent may be used in the treatment of a mixture comprising a plurality of fluorescent microparticles in accordance with the wavelength range of the excitation light or emitted light. For example, when obtaining white light by irradiating excitation light in the ultraviolet range, it is preferable to surface-treat a mixture of fluorescent microparticles which emit blue, green, yellow, and red fluorescent light.

Metal oxide microparticles have a high refractive index, and microparticles so small that light scattering can be ignored can be easily obtained, so metal oxide microparticles are widely used in optical materials which require a high refractive index and high transparency, in particular. The average particle size of such metal oxide microparticles is within the range of 1 to 500 nm and particularly preferably from 1 to 100 nm, and the range of 1 to 20 nm is even more preferable from the perspective of the transparency of the optical material containing the microparticles. Further, with the objective of improving the optical, electromagnetic, and mechanical characteristics of optical materials, these metal oxide microparticles may be—and are preferably—nanocrystalline particles with a crystal diameter of 10 to 100 nm.

Examples of metal oxide microparticles include barium titanate, zirconium oxide, aluminum oxide (alumina), silicon oxide (silica), titanium oxide, strontium titanate, barium titanate zirconate, cerium oxide, cobalt oxide, indium tin oxide, hafnium oxide, yttrium oxide, tin oxide, niobium oxide, and iron oxide. In particular, a metal oxide containing at least one type of metal element selected from titanium, zirconium, and barium is preferable from the perspective of optical properties and electrical properties.

In particular, zirconium oxide has a relatively high refractive index (refractive index: 2.2) and is therefore useful for optical material applications which require a high refractive index and high transparency. Similarly, barium titanate has a high dielectric constant and refractive index and is useful for imparting optical and electromagnetic performance to organic materials, but the surface treatment agent for an optical material of the present invention makes it possible to finely and stably disperse metal oxide microparticles into a hydrophobic curable resin as a result of surface treatment with metal oxide microparticles such as barium titanate, which makes it possible to compound large quantities more stably than untreated microparticles. This results in the advantage that the optical properties (in particular, the high refringency) and electromagnetic properties of the resulting optical member can be dramatically improved.

Metal microparticles are conductive and may improve functionality when formed as metal nanoparticles with an average particle size of a few nm to several 10 nm. However, fusion may occur between the microparticles when the surfaces make direct contact with one another, which causes metal nanoparticles to agglomerate together and leads to the problem that the uniform dispersibility of the dispersion system is lost. By using the surface treatment agent for an optical material of the present invention, it is possible to align or bond an organic silicon compound with the surface of metal nanoparticles and to prevent the aggregation of metal nanoparticles or the like, which has the advantage that it is not only possible to improve the fine dispersibility and dispersion stability, but it is also possible to improve functionality such as the prevention of precipitation or oxidation in the curable resin.

The metal microparticles may be particles consisting of a single metal, alloy particles consisting of two or more metal elements (for example, 2-element alloy particles, 3-element alloy particles, 4-element alloy particles, or multi-element alloy particles), semiconductor particles, magnetic particles, fluorescent particles, conductive particles, or pigment particles. In addition, alloy particles partially containing carbon may be used as semiconductor particles.

Examples of these metal microparticles include particles consisting of elements selected from group 11 elements of the long periodic table such as Cu, Ag, and Au (copper group elements), group 8 to 10 elements of the periodic table such as Fe, Co, Ni, Ru, Rh, Pd, Os, Ir, and Pt (iron group elements and/or platinum group elements), group 12 elements of the periodic table such as Zn, Cd, and Hg (zinc group elements), group 7 elements of the periodic table such as Mn, Tc, and Re (manganese group elements), group 6 elements of the periodic table such as Cr, Mo, and W (chromium group elements), group 5 elements of the periodic table such as V, Nb, and Ta (earth acid metal elements), group 4 elements of the periodic table such as Ti, Zr, and Hf (titanium group elements), group 3 elements of the periodic table such as Sc, Y, lanthanoids (for example, La, Ce, Pr, Nd, Sm, Eu, Gd, Tb, Dy, Ho, Er, Yb, Lu, and the like), actinoids (Ac, Th, and the like), and misch metals (including rare earth elements), group 13 elements of the periodic table such as B, Al, Ga, In, and Tl (aluminum group elements), group 14 elements of the periodic table such as Si, Ge, Sn, and Pb (carbon group elements), group 15 elements of the periodic table such as As, Sb, and Bi, group 16 elements such as Te and Po, and group 2 elements of the periodic table such as Mg, Ca, Sr, and Ba. These metal microparticles may be used alone or may contain a plurality of elements. In addition, alloys containing two or more types of elements selected from the elements described above may be used.

A nanocrystal structure—nanocrystal structure for a semiconductor, in particular—is useful as an optical material such as a light-emitting semiconductor such as an LED and particularly as a radiator or wavelength conversion material which transforms into a light-emitting material or fluorescent material, in that the light emission wavelength can be controlled in accordance with the size of the nanocrystals and the particles due to the quantum containment effect and, in particular, in that semiconductor nanocrystals called quantum dots enable the control of the wavelength of luminescent light emission covering the entire visible spectrum by means of the control of the nanocrystal particle size. These nanocrystal structures consist of Si nanocrystals, group II-VI compound semiconductor nanocrystals, group III-V compound semiconductor nanocrystals, group IV-VI compound semiconductor nanocrystals, and mixtures thereof. In particular, group II-VI semiconductor nanocrystals typified by CdSe semiconductors, group III-V compound semiconductor nanocrystals typified by GaN semiconductors, and group IV-VI compound semiconductor nanocrystals typified by SbTe semiconductors are used. These semiconductor nanocrystals may be obtained by gas-phase growth at a high temperature or may be colloidal semiconductor nanocrystals synthesized by an organochemical method (including a gas-phase method). The nanocrystals may also have a core-structure.

The average particle size of the nanocrystal structures used in a light-emitting semiconductor—quantum dots, in particular—is within the range of approximately 0.1 nm to several 10 s of nm and is selected in accordance with the light emission wavelength. By surface-treating these nanocrystals with the surface treatment agent for an optical material of the present invention, it is possible to align or bond an organic silicon compound with the nanocrystal surface so as to prevent the aggregation thereof, which makes it possible not only to improve the fine dispersibility and dispersion stability, but also to further improve the light emission characteristics and light extraction efficiency in a curable resin.

Part or entire surface of these fluorescent microparticles, metal oxide microparticles, metal microparticles, nanocrystal structures, and quantum dots used in the present invention may be covered by a silica layer. By covering some or entire surface functional groups of these microparticles with a silica layer, it is possible to reduce photocatalytic activity and thermocatalytic reactivity.

In addition, the surface treatment agent for an optical material of the present invention may also be a conventionally known inorganic material and may be used in the treatment of a substrate used in an optical material. Examples include talc, clay, mica powders, glass powders (glass beads), glass frits, glass cloths, glass tapes, glass mats, glass paper, glass sheets, mica sheets, stainless steel sheets, nitrides such as silicon nitride, boron nitride, and aluminum nitride, silicon carbide, diamond particles, carbon nanotubes, or substances in which the surfaces thereof are partially or completely covered by a silica layer. These may also be used as fillers or thermally conductive materials.

The surface treatment method of these optical materials is not particularly limited, and a known method may be used. An example is a method of stirring an optical material and the surface treatment agent for an optical material of the present invention in a solvent for 0.1 to 72 hours at 10 to 100° C. using a mechanical force, ultrasonic waves, or the like (wet method). The resulting surface-treated optical material can be compounded with a curable resin composition or the like while dispersed in this solvent and may also be compounded with another curable resin composition or the like in a dry system as a surface treatment material in a state in which the solvent has been removed. In addition, since the average particle size of the optical material—a microparticulate member, in particular—fluctuates very little due to surface treatment with the method described above, the average particle size of the microparticulate member used in surface treatment should be adjusted in advance in accordance with a known method in order to obtain a microparticulate member having a desired average particle size after surface treatment.

The amount of the surface treatment agent for an optical material of the present invention that is used is preferably from 0.1 to 500 parts by mass and particularly preferably from 1.0 to 250 parts by mass per 100 parts by mass of the member for the optical material to be surface-treated, and the range of 5.0 to 100 parts by mass is most preferable. In particular, in the case of an optical fine member with a small particle size of at most a few tens of nm, it is preferable to add at least 100 parts by mass of the surface treatment agent for an optical material of the present invention to 100 parts by mass of the member.

In the wet method described above, the apparatus used for the dispersion and stirring of the optical material and the surface treatment agent for an optical material of the present invention is not particularly limited, and two or more types of dispersion devices may also be used in stages. Specific examples of devices used for dispersion and stirring include a homo mixer, a paddle mixer, a Henschel mixer, a line mixer, a homo disper, a propeller agitator, a vacuum kneader, a homogenizer, a kneader, a dissolver, a high-speed dispenser, a sand mill, a roll mill, a ball mill, a tube mill, a conical mill, an oscillating ball mill, a high swing ball mill, a jet mill, an attritor, a dyno mill, a GP mill, a wet atomization device (Altimizer or the like manufactured by Sugino Machines), an ultrasonic dispersion device (ultrasonic homogenizer), a bead mill, a Banbury mixer, a stone mortar mill, and a grindstone-type pulverizer. In particular, in order to disperse inorganic particles into fine particles with an average particle size of at most 100 nm, dispersion with an ultrasonic dispersion device or bead mill which promotes dispersion by beans of the shearing force caused by the friction of minute beads is preferable. Examples of such a bead mill include the “Ultra Apex Mill” (trade name) manufactured by Kotobuki Industries (Ltd.) and the “Star Mill” (trade name) manufactured by Ashizawa Fine Tech (Ltd.). The beads that are used are preferably glass beads, zirconia beads, alumina beads, magnetic beads, styrene beads, or the like. When an ultrasonic dispersion device is used, it is preferable to use an ultrasonic homogenizer with a rated output of at least 300 W. These ultrasonic homogenizers are commercially available from Nippon Seiki Co., Ltd., Mitsui Electric Co., Ltd., or the like.

The surface treatment agent for an optical material of the present invention may further be used in a synthesis process or post-treatment step of one or more optical fine members selected from the aforementioned fluorescent microparticles, metal oxide microparticles, metal microparticles, nanocrystal structures, and quantum dots, or members in which part or entire surface of these members is covered by a silica layer. The usage method in the synthesis process or post-treatment step is not particularly limited, but an example of a solid-phase method is a method of treating the surface of an optical member such as a fluorescent substance, a metal oxide, or a nanocrystal structure prior to refinement of a member in which part or entire surface thereof is covered by a silica layer using the surface treatment agent of the present invention and then dispersing or finely pulverizing the substance using a mechanical force, ultrasonic waves, or the like. The apparatus described above is an example of the apparatus used for dispersion or pulverization.

Conventionally known methods can be used, such as a method of dispersing these fine members in an appropriate solvent and then adding a sodium silicate aqueous solution under acidic conditions, a method of adding a silicic acid solution, or a method of hydrolyzing hydrolyzable 4-functional silanes in the presence of an acidic or basic catalyst.

On the other hand, the surface treatment agent for an optical material of the present invention may also be used in the synthesis of an optical fine member produced by a liquid-phase method. When the surface treatment agent for an optical material of the present invention is used in a liquid-phase synthesis method, the particle surface of the resulting optical fine member is partially or completely covered by the organic silicon compound of the present invention in the particle formation process. Therefore, there is not only the advantage that it is possible to finely and uniformly disperse the substance in the re-dispersion step, but also the advantage that the surface characteristics of the resulting optical fine member can be designed as desired by selecting the refractive index of the organic silicon compound or the types of the reactive functional groups used. Further, performing liquid-phase synthesis in the presence of the surface treatment agent for an optical material of the present invention yields the advantage that it is possible to synthesize optical fine members of various shapes such as metal nanoparticles, semiconductor nanoparticles, core-shell nanoparticles, doped nanoparticles, nano rods, and nano plates surface-treated at the time of synthesis with a unified process.

Specifically, the synthesis of an optical fine member by a liquid-phase method comprises:

step 1: a step of dispersing or mixing a precursor substance of the optical fine member and the surface treatment agent for an optical material of the present invention (organic silicon compound) into a reaction medium;
step 2: a step of optionally adding and dispersing or mixing a substance (primarily a reducer) that is reactive with the precursor substance of the optical fine member;
step 3: a step of implementing nucleus formation in the mixed solution of the precursor substance described above by heating the entire system to a temperature at which the nucleus formation of the desired optical fine member will progress (preferably a temperature exceeding 200° C., and a temperature between room temperature and approximately 60 degrees in the gas of a sol gel method) and optionally establishing high-pressure conditions;
step 4: a step of realizing the particle growth of the optical fine member by controlling the temperature of the entire system and performing surface treatment with the organic silicon compound described above; and
step 5: a step of forming the desired optical fine member by means of a liquid-phase reaction and then lowering the temperature of the entire system to stop particle growth (quench).
The surface treatment agent for an optical material of the present invention is preferably added to the mixed solution of the precursor substance of the optical fine member in the stage of step 1 or 2 and may also be used in combination with an optional surfactant or other surface treatment agent.

The optical fine member surface-treated by the surface treatment agent of the present invention resulting from the steps described above may be concentrated or separated from the reaction solution by using typical methods such as ultrafiltration, membrane filtration, dialysis, and centrifugation, for example. In addition, when the reaction medium is hydrophilic, the member may also be separated from contaminants or the raw material substance by performing phase separation, phase distribution, or the like using a hydrophobic organic solvent. Solvent extraction, chromatography, and the like may also be suitably used.

The appropriate reaction medium is not particularly limited as long as it is a liquid medium and enables the uniform dispersion of the precursor substance of the optical fine member and the surface treatment agent for an optical material of the present invention, and examples include organic solvents such as alcohol solvents (for example, methanol, ethanol, 2-methoxyethanol, 2-ethoxyethanol, 2-propanoxyethanol, 2-propanol, and the like), ketone solvents (methyl ethyl ketone, acetyl acetone(pentane-2,4-dion), acetone and the like), trioctylphosphane oxide, octadecene, silicone oils, alkyl aromatic compounds, alkyl phenyl ethers, partially hydrogenated phenyls, terphenyls, and polyphenyls or mixed solvents in which any two or more types of these compounds are mixed at any ratio. Similarly, water, subcritical water, or supercritical water may be used. In particular, a liquid medium that can be heated to a temperature of at least 200° C. is preferable when performing a reaction under high-pressure conditions or the like.

The precursor substance of the optical fine member is not particularly limited as long as the substance is soluble in the reaction medium described above and can be used to form the desired particles, and primary examples include metal complex compounds such as metal halides, metal carbonates, metal carboxylates, metal alkoxides, metal alkyl xanthogenates, and metal carbonyl compounds, metal hydroxides, and the like. One type of these substances may be used alone, or two or more types may be used in any combination and at any ratio. The precursor substance may be present in any state in the reaction medium, but the precursor substance is ordinarily present in the dissolved state. Further, a compound containing the constituent elements described above may also be present so as to be used as a substance for providing the constituent elements of a desired optical fine member.

The substance that is reactive with the precursor substance of the optical fine member is primarily a reducer and may be in the liquid form or the gaseous form. Specific examples include formic acid, hydrogen gas, carbon monoxide gas, synthetic gas, aqueous gas, mixtures of oxygen and carbon monoxide, and mixtures thereof. Using these reactive substances yields the advantage that metal microparticles in which the precursor substance is reduced can be obtained.

The synthesis reaction by the liquid-phase method described above can be performed in any apparatus capable of achieving conditions under which the core formation of the optical fine member can be realized, and the device may be selected from devices widely known to people having ordinary skill in the art in the field of microparticle formation using a sol gel method, a metal nanoparticle synthesis method, or the like under high temperature and high pressure conditions. For example, a batch device can be used. When metal oxide particles are obtained by means of a sol gel reaction, an open reaction device such as an oven may be used, but when subcritical water or supercritical water is used as the reaction medium, it is preferable to use an autoclave (pressure-resistance reaction vessel) and particularly preferable to use an autoclave-type reactor.

The temperature conditions (core formation and particle growth), pressure conditions, and temperature reducing conditions used in the synthesis reaction and surface treatment described above must be designed in accordance with the type of the reaction, the device, the reaction scale, the reaction medium, and the type of the raw material in order to obtain the desired optical fine member. In addition, the ratio of the precursor substance and the reducer in the mixed solution of the precursor is not particularly limited and can be determined appropriately by experimentation or the like so that the desired optical fine member can be obtained. For example, the ratio of the precursor substance to the reducer may be adjusted within the range of approximately 1:1,000 to 1,000:1, preferably from approximately 1:50 to 50:1, and more preferably from approximately 1:15 to 15:1 when expressed as a molar ratio. Similarly, the ratio of the precursor substance and the surface treatment agent in the mixed solution can be designed experimentally or the like so as to provide the desired surface characteristics, but the ratio is typically within the range of approximately 1:50 to 50:1.

The present invention further provides an optical material containing a member for an optical material which is surface-treated as described above. More specifically, the present invention provides an optical material containing a member for the optical material, the surface treatment agent for an optical material described above, and a curable resin composition and is produced when the member for the optical material is compounded with the curable resin composition after being surface-treated in advance with the surface treatment agent for an optical material described above.

In particular, the surface treatment agent for an optical material of the present invention is useful for the surface treatment of one or more optical fine members selected from fluorescent microparticles, metal oxide microparticles, metal microparticles, nanocrystal structures, and quantum dots used in an optical semiconductor, or members in which part or entire surface of these members is covered by a silica layer and is an optical material containing:

(A) at least one optical fine member selected from fluorescent microparticles, metal oxide microparticles, metal microparticles, nanocrystal structures, and quantum dots or members in which part or entire surface of these members is covered by a silica layer;
(B) the surface treatment agent for an optical material according to one of claims 1 to 9; and
(C) a curable resin composition;
wherein the microparticles serving as component (A) are preferably dispersed in the curable resin composition serving as component (C) after being surface-treated by the surface treatment agent for an optical material serving as component (B).

Examples of (C) curable resins include phenol resins, formaldehyde resins, xylene resins, xylene-formaldehyde resins, ketone-formaldehyde resins, furan resins, urea resins, imide resins, malamine resins, alkyd resins, unsaturated polyester resins, aniline resins, sulfone-amide resins, silicone resins, epoxy resins, copolymer resins thereof, and mixtures of two more types of these resins. It is useful for the surface treatment agent for an optical material of the present invention to be used, and, in particular, for the curable resin to be a silicone resin in that the hydrophobic siloxane portion improves the affinity with the silicone resin, which makes it possible to achieve stable dispersion, to increase the refractive index of the silicone resin while maintaining transparency and heat resistance, and to improve functionality.

In particular, the silicone resin described above is preferably a silicone resin which is cured by a condensation reaction of a hydrosilylation reaction. When the surface treatment agent for an optical material serving as component (B) described above consists of an organic silicon compound further having condensation-reactive or hydrosilylation-reactive functional groups, the reactive functional groups in the organic silicon compound aligned with or bonded to the surface of the member for the optical material and the component of the surrounding curable silicone resin are bonded by a condensation reaction or a hydrosilylation reaction. As a result, a structure in which the fine member for the optical material serving as component (A) is uniformly and stably dispersed is obtained, and the functionality and optical transmittance of the cured resin composition are further improved.

In particular, it is particularly preferable for the curable resin composition to contain (D) a fluorescent substance. Examples of these fluorescent substances include yellow, red, green, and blue light-emitting fluorescent substances consisting of oxide-type fluorescent substances, oxynitride fluorescent substances, nitride-type fluorescent substances, sulfide-type fluorescent substances, oxysulfide-type fluorescent substances, or the like which are widely used in the light emitting diode (LED), and these are common to the components given as examples of the fluorescent microparticles described above. In addition, these fluorescent substances may be surface-treated by component (A), and a mixture of one or two or more fluorescent substances may be used.

In the curable resin composition described above, the content of the fluorescent microparticles is not particularly limited but is within the range of 0.1 to 70 wt. % and more preferably within the range of 1 to 20 M. % of the entire curable resin composition.

In addition, as long as the object of the present invention is not inhibited, this composition may also contain inorganic powders such as fumed silica, sedimentary silica, molten silica, fumed titanium oxide, quartz powder, glass powder (glass beads), aluminum hydroxide, magnesium hydroxide, silicon nitride, aluminum nitride, boron nitride, silicon carbide, calcium silicate, magnesium silicate, diamond particles, and carbon nanotubes; or organic resin fine powders such as polymethacrylate resins, and it is preferable for some or all of these materials to be surface-treated with component (B).

The curable resin composition described above may also contain additives such as anti-aging agents, denaturing agents, surfactants, dyes, pigments, anti-discoloration agents, and ultraviolet absorbers as long as the effect of the present invention is not inhibited. In addition, the curable resin composition can be used as an optical semiconductor element sealing material, in particular, and an optical semiconductor device can be produced by first applying the resin to an appropriate thickness by means of a method such as casting, spin coating, or roll coating or covering the substance by means of potting and then heating and drying the substance.

The optical material of the present invention is excellent with regard to optical transmittance and the expected functionality since the optical fine member is finely, uniformly, and stably dispersed in the curable resin, so the optical material is suitably used as a sealing material for an optical semiconductor element or an optical lens material. Accordingly, with the present invention, it is possible to provide an optical member such as a sealing material for an optical semiconductor element or an optical semiconductor lens containing the surface treatment agent for an optical material of the present invention and an optical semiconductor device which uses the optical member.

### EXAMPLES

Hereinafter, the present invention is described in detail with reference to Practical Examples and Comparative Examples, but it should be understood that the present invention is not limited to these Practical Examples. The viscosity (kinetic viscosity) values are measured at 25° C. In the composition formulae described below, Vi represents a vinyl group, Me represents a methyl group, Ph represents a phenyl group, and Np represents a naphthyl group. The refractive index was measured at 25° C. and 590 nm for liquid products and at 25° C. and 633 nm for cured products. The transmittance indicates the transmittance of light with a wavelength of 580 nm at a thickness of 10 μm. The end points of the reactions in each of the synthesis examples was confirmed by collecting part of the sample and confirming the consumption of reactive functional groups by infrared spectroscopy (hereafter called “IR analysis”). The average structural formulas and the numbers of silicon atoms excluding —Si(OMe)₃ in one molecule were confirmed by means of nuclear magnetic resonance. (NMR hereafter) for surface treatment agent Nos. 20 to 24 obtained by Synthesis Examples 10 to 14.

### Synthesis Example 1

First, 450 g (125.5 millimoles) of a phenylmethylpolysiloxane capped at both terminals with vinyl dimethylsiloxy groups represented by the average structural formula:

ViMe₂Si(OSiMePh)₂₅OSiMe₂Vi was mixed with a complex of platinum and 1,3-divinyltetramethyldisiloxane in an amount so that the platinum metal content was 2 ppm with respect to the total amount of the reaction mixture. After this was heated to 90° C., 35.4 g (125.5 millimoles) of a compound represented by the average structural formula:
HMe₂SiOSiMe₂C₂H₄Si(OMe)₃ was dripped into the mixture. After the mixture was stirred for 1 hour at 100° C., part of the mixture was sampled. When IR analysis was performed, it was observed that the SiH groups had been completely consumed. The low-boiling point matter was removed by heating under reduced pressure,
and 483 g of silethylene silicone with the following average structure (surface treatment agent No. 1) was obtained as a clear, colorless liquid (yield: 99.5%).

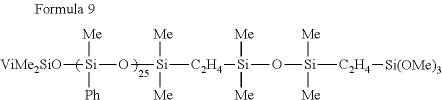

The refractive index was 1.5360.

### Synthesis Example 2

First, 20 g (4.3 millimoles) of a phenylmethylsiloxane diphenyl siloxane copolymer capped at both terminals with vinyldimethylsiloxy groups represented by the average structural formula:

ViMe₃Si(OSiMePh)₁₃(OSiPh)₂)₁₃OSiMe₂Vi was mixed with a complex of platinum and 1,3-divinyltetramethyldisiloxane in an amount so that the platinum metal content was 2 ppm with respect to the total amount of the reaction mixture. After this was heated to 90° C., 1.21 g (4.3 millimoles) of a compound represented by the average structural formula:
HMe₂SiOSiMe₂C₂H₄Si(OMe)₃ was dripped into the mixture. After the mixture was stirred for 0.5 hour at 100° C., part of the mixture was sampled. When IR analysis was performed, it was observed that the SiH groups had been completely consumed. The low-boiling point matter was removed by heating under reduced pressure,
and 20.7 g of silethylene silicone with the following average structure (surface treatment agent No. 2) was obtained as a clear, colorless liquid (yield: 97.6%).

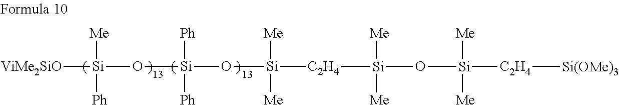

The refractive index was 1.5760.

### Synthesis Example 3

First, 25 g (25.6 millimoles) of a phenylmethylpolysiloxane capped at both terminals with vinyl dimethylsiloxy groups represented by the average structural formula:

ViMe₂Si(OSiMePh)₆OSiMe₂Vi was mixed with a complex of platinum and 1,3-divinyltetramethyldisiloxane in an amount so that the platinum metal content was 2 ppm with respect to the total amount of the reaction mixture. After this was heated to 90° C., 7.22 g (25.6 millimoles) of a compound represented by the average structural formula:
HMe₂SiOSiMe₂C₂H₄Si(OMe)₃ was dripped into the mixture. After the mixture was stirred for 0.5 hour at 100° C., part of the mixture was sampled. When IR analysis was performed, it was observed that the SiH groups had been completely consumed. The low-boiling point matter was removed by heating under reduced pressure,
and 32.2 g of silethylene silicone with the following average structure (surface treatment agent No. 3) was obtained as a clear, colorless liquid (yield: 99.3%).

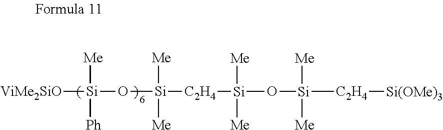

The refractive index was 1.5012.

### Synthesis Example 4

First, 25 g of a methyl phenyl siloxane methyl vinyl siloxane copolymer capped at both terminals with diphenylmethylsilyl groups represented by the average structural formula:

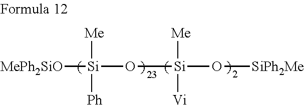

(vinyl group content: 13.5 millimoles) was mixed with a complex of platinum and 1,3-divinyltetramethyldisiloxane in an amount so that the platinum metal content was 2 ppm with respect to the total amount of the reaction mixture. After this was heated to 90° C., 1.9 g (6.7 millimoles) of a compound represented by the average structural formula:
HMe₂SiOSiMe₂C₂H₄Si(OMe)₃ was dripped into the mixture. After the mixture was stirred for 1 hour at 120° C., part of the mixture was sampled. When IR analysis was performed, it was observed that the SiH groups had been completely consumed. The low-boiling point matter was removed by heating under reduced pressure,
and 26.4 g of silethylene silicone with the following average structure (surface treatment agent No. 4) was obtained as a clear, colorless liquid (yield: 98.0%).

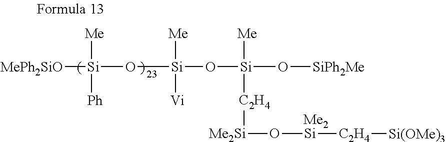

The refractive index was 1.5420.

### Synthesis Example 5

First, 30 g of a methyl phenyl siloxane methyl vinyl siloxane copolymer capped at both terminals with diphenylmethylsilyl groups represented by the average structural formula:

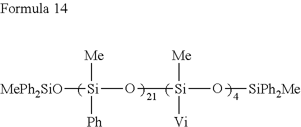

(vinyl group content: 33.2 millimoles) was mixed with a complex of platinum and 1,3-divinyltetramethyldisiloxane in an amount so that the platinum metal content was 2 ppm with respect to the total amount of the reaction mixture. After this was heated to 90° C., a mixture of 2.3 g (8.3 millimoles) of a compound represented by the average structural formula:
HMe₂SiOSiMe₂C₂H₄Si(OMe)₃ and 2.3 g (8.3 millimoles) of 1,1,3-trimethyl-3,3-diphenyldisiloxane was dripped into the mixture. After the mixture was stirred for 1 hour at 120° C., part of the mixture was sampled. When IR analysis was performed, it was observed that the SiH groups had been completely consumed. The low-boiling point matter was removed by heating under reduced pressure,
and 34.2 g of silethylene silicone with the following average structure (surface treatment agent No. 5) was obtained as a clear, colorless liquid (yield: 98.8%).

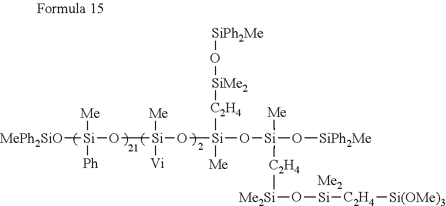

The refractive index was 1.5387.

### Synthesis Example 6

First, 25 g of a methyl phenyl siloxane methyl vinyl siloxane copolymer capped at both terminals with diphenylmethylsilyl groups represented by the average structural formula:

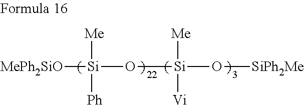

(vinyl group content: 20.5 millimoles) was mixed with a complex of platinum and 1,3-divinyltetramethyldisiloxane in an amount so that the platinum metal content was 2 ppm with respect to the total amount of the reaction mixture. After this was heated to 90° C., 1.9 g (6.8 millimoles) of a compound represented by the average structural formula:
HMe₂SiOSiMe₂C₂H₄Si(OMe)₃ was dripped into the mixture. After the mixture was stirred for 2 hour at 120° C., part of the mixture was sampled. When IR analysis was performed, it was observed that the SiH groups had been completely consumed. The low-boiling point matter was removed by heating under reduced pressure,
and 26.4 g of silethylene silicone with the following average structure (surface treatment agent No. 6) was obtained as a clear, colorless liquid (yield: 97.8%).

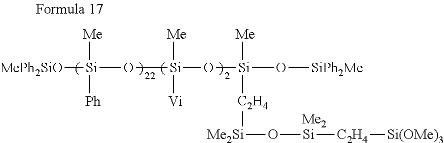

The refractive index was 1.5395.

### Synthesis Example 7

First, 25 g of a methyl phenyl siloxane methyl vinyl siloxane copolymer capped at both terminals with diphenylmethylsilyl groups represented by the average structural formula:

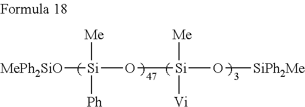

(vinyl group content: 10.6 millimoles) was mixed with a complex of platinum and 1,3-divinyltetramethyldisiloxane in an amount so that the platinum metal content was 2 ppm with respect to the total amount of the reaction mixture. After this was heated to 90° C., 1.0 g (3.5 millimoles) of a compound represented by the average structural formula:
HMe₂SiOSiMe₂C₂H₄Si(OMe)₃ was dripped into the mixture. After the mixture was stirred for 1.5 hour at 120° C., part of the mixture was sampled. When IR analysis was performed, it was observed that the SiH groups had been completely consumed. The low-boiling point matter was removed by heating under reduced pressure,
and, 26.4 g of silethylene silicone with the following average structure (surface treatment agent No. 7) was obtained as a clear, colorless liquid (yield: 97.8%).

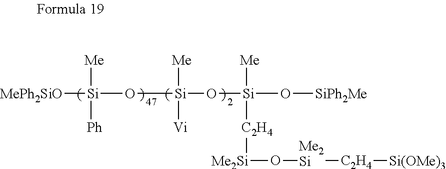

The refractive index was 1.5450.

### Synthesis Example 8

First, 35 g of a methyl phenyl siloxane methyl vinyl siloxane copolymer capped at both terminals with diphenylmethylsilyl groups represented by the average structural formula:

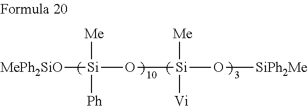

(vinyl group content: 51.8 millimoles) was mixed with a complex of platinum and 1,3-divinyltetramethyldisiloxane in an amount so that the platinum metal content was 2 ppm with respect to the total amount of the reaction mixture. After this was heated to 90° C., 4.9 g (17.3 millimoles) of a compound represented by the average structural formula:
HMe₂SiOSiMe₂C₂H₄Si(OMe)₃ was dripped into the mixture. After the mixture was stirred for 2 hour at 120° C., part of the mixture was sampled. When IR analysis was performed, it was observed that the SiH groups had been completely consumed. The low-boiling point matter was removed by heating under reduced pressure,
and 39.2 g of silethylene silicone with the following average structure (surface treatment agent No. 8) was obtained as a clear, colorless liquid (yield: 98.3%).

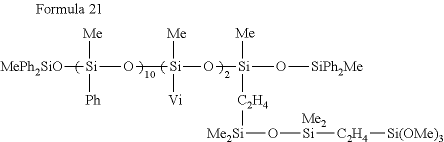

The refractive index was 1.5314.

### Synthesis Example 9

First, 40 g (11.2 millimoles) of a phenylmethylpolysiloxane capped at both terminals with vinyl dimethylsiloxy groups represented by the average structural formula:

ViMe₂Si(OSiMePh)₂₅OSiMe₂Vi was mixed with a complex of platinum and 1,3-divinyltetramethyldisiloxane in an amount so that the platinum metal content was 2 ppm with respect to the total amount of the reaction mixture. After this was heated to 90° C., 4.4 g (11.2 millimoles) of a compound represented by the average structural formula:
HMe₂SiOSiMe₂C₁₀H₂₀COOSiMe₃ was dripped into the mixture. After the mixture was stirred for 1 hour at 100° C., part of the mixture was sampled. When IR analysis was performed, it was observed that the SiH groups had been completely consumed. Next, 40 cc of tetrahydrofuran and 1.6 g of water were added and heat-refluxed for 3 hours to perform a desilylation reaction. The low-boiling point matter was removed by heating under reduced pressure,
and, 43.4 g of silethylene silicone with the following average structure (surface treatment agent No. 9) was obtained as a clear, colorless liquid (yield: 97.7%).

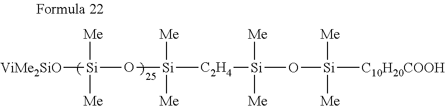

The refractive index was 1.5360.

### Synthesis Example 10

First, 16.5 g of a vinyl functional silicone resin having a vinyl group content of 5.6 wt. % and represented by the compositional formula (Me₂ViSiO_{1/2})(PhSiO_{3/2})₃ (vinyl group content: 34.3 millimoles),

4.8 g (17.2 millimoles) of disiloxane represented by the general formula:
HMe₂SiOSiMe₂C₂H₄Si(OMe)₃, and a complex catalyst consisting of platinum and 1,3-divinyltetramethyldisiloxane in an amount so that the platinum metal content was 2 ppm with respect to the total amounts described above were added, and 13.5 g of toluene was further added and dissolved in the mixture. After this mixture was stirred for 1 hour at 100° C., the mixture was sampled. When the sample was analyzed by infrared spectroscopy, it was observed that the absorption of SiH groups had been eliminated and that the addition reaction was completed. The product was 34.8 g of a toluene solution containing 21.3 g of an addition reaction product (surface treatment agent No. 20) containing 17.1 millimoles of residual vinyl groups and 17.1 millimoles of Si(OMe)3 groups (concentration: 61.3 wt. %).

### Synthesis Example 11

First, 19.7 g of a vinyl functional silicone resin having a vinyl group content of 6.4 wt. % and represented by the compositional formula (Me₂ViSiO_{1/2})₂(NpSiO_{3/2})₃ (vinyl group content: 46.5 millimoles), 6.6 g (23.3 millimoles) of disiloxane represented by the general formula: HMe₂SiOSiMe₂C₂H₄Si(OMe)₃, and a complex catalyst consisting of platinum and 1,3-divinyltetramethyldisiloxane in an amount so that the platinum metal content was 2 ppm with respect to the total amounts described above were added, and 19.7 g of toluene was further added and dissolved in the mixture. After this mixture was stirred for 1 hour at 100° C., the mixture was sampled. When the sample was analyzed by infrared spectroscopy, it was observed that the absorption of SiH groups had been eliminated and that the addition reaction was completed. The product was 46.0 g of a toluene solution containing 26.3 g of an addition reaction product (surface treatment agent No. 21) containing 23.3 millimoles of residual vinyl groups and 23.3 millimoles of Si(OMe)3 groups (concentration: 57.2 wt. %).

### Synthesis Examples 12 and 13

The amount of disiloxane represented by the general formula: HMe₂SiOSiMe₂C₂H₄Si(OMe)₃ in Synthesis Example 10 was changed as shown in the following Table 1 to obtain toluene solutions of addition reaction products with different Vi group contents and (MeO)₃Si group contents.

TABLE 1

| | Synthesis Exam- | Synthesis Exam- |
|---|---|---|
| | ple 12 (Surface | ple 13 (Surface |
| | treatment agent | treatment agent |
| | No. 22) | No. 23) |
| (Me₂ViSiO_{1/2})(PhSiO_{3/2})₃ | 16.5 g | 16.5 g |
| | (Vi content: | (Vi content: |
| | 34.3 mmol) | 34.3 mmol) |
| HMe₂SiOSiMe₂C₂H₄Si(OMe)₃ | 2.4 g | 1.2 g |
| | (8.6 mmol) | (4.3 mmol) |
| Vi group/SiH group molar ratio | 4 | 8 |
| Adduct weight | 18.9 g | 17.7 g |
| Toluene solution weight | 32.4 g | 31.2 g |
| Toluene solution concentration | 58.4% | 56.7% |

### Synthesis Example 14

First, 18.2 g of a vinyl functional silicone resin having a vinyl group content of 5.6 wt. % and represented by the compositional formula (Me₂ViSiO₁₂)(PhSiO_{3/2})₃ (vinyl group content: 37.9 millimoles),

1.85 g (4.74 millimoles) of disiloxane represented by the general formula:
HMe₂SiOSiMe₂C₁₀H₂₀COOSiMe₃, and a complex catalyst consisting of platinum and 1,3-divinyltetramethyldisiloxane in an amount so that the platinum metal content was 2 ppm with respect to the total amounts described above were added, and 15 g of toluene was further added and dissolved in the mixture. After this mixture was stirred for 1 hour at 100° C., the mixture was sampled. When the sample was analyzed by infrared spectroscopy, it was observed that the absorption of SiH groups had been eliminated and that the addition reaction was completed. A desilylation reaction of the silyl ester groups was performed by adding 1.23 g (38.6 millimoles) of methanol and stirring for 2 hours at 80° C. The product was 36.3 g of a solution in which 19.7 g of an addition reaction product (surface treatment agent No. 24) containing 37.9 millimoles of residual vinyl groups and 4.74 millimoles of COOH groups was dissolved in a mixed solvent primarily consisting of toluene (concentration: 54.4 wt. %).

### Synthesis Example 15

First, 193.2 g (708.8 milliomoles) of 1,1-diphenyl-1,3,3-trimethyldisiloxane and a complex catalyst consisting of platinum and 1,3-divinyltetramethyldisiloxane were added in an amount equivalent to 2 ppm of the total amount of the reaction mixture in a nitrogen atmosphere. The mixture was heated to 80° C., and 200 g (779.8 millimoles) of trimethylsilyl undecylenate was dripped into the mixture at a temperature of 85° C. to 88° C. After dripping was complete, the mixture was stirred for 1 hour at 100° C. The mixture was sampled, and when the sample was analyzed by infrared spectroscopy, it was observed that the absorption of SiH groups had been eliminated and that the addition reaction was completed. Next, 350 g of tetrahydrofuran and 68 g (3.8 moles) of water were added and stirred while heating for 2.5 hours at 60° C. to perform a desilylation reaction. After the mixture was cooled to room temperature, 150 g of toluene was added, and the mixture was left to stand for the purpose of phase separation. The aqueous phase was removed, and molecular sieves were added to the organic layer, which was then left to dry overnight. The molecular sieves were removed by filtering the organic layer, and the filtrate was removed by heating under reduced pressure to obtain 335.6 g of disiloxane (surface treatment agent No. 25) represented by the structural formula: Ph₂MeSiOSiMe₂C₁₀H₂₀COOH (yield: 99.6%).

### Synthesis Example 16

With the exception of using 6 g (17.9 millimoles) of 1,1,1-triphenyl-3,3-dimethyldisiloxane instead of 1,1-diphenyl-1,3,3-trimethyldisiloxane, 9.4 g of disiloxane (surface treatment agent No. 26) represented by the structural formula: Ph₃SiOSiMe₂C₁₀H₂₀COOH was obtained as the target product in the same manner as in Synthesis Example 15 (yield: 97.6%).

### Synthesis Example 17

First, 35 g (128.4 milliomoles) of 1,1-diphenyl-1,3,3-trimethyldisiloxane and a complex catalyst consisting of platinum and 1,3-divinyltetramethyldisiloxane were added in an amount equivalent to 2 ppm of the total amount of the reaction mixture in a nitrogen atmosphere. The mixture was heated to 80° C., and 22.9 g (141.3 millimoles) of allyltrimethoxysilane was dripped into the mixture at a temperature of 80° C. to 89° C. After dripping was complete, the mixture was stirred for 1 hour at 90° C. The mixture was sampled, and when the sample was analyzed by infrared spectroscopy, it was observed that the absorption of SiH groups had been eliminated and that the addition reaction was completed. The low-boiling point matter was removed by heating under reduced pressure, and 55.2 g of disiloxane (surface treatment agent No. 27) represented by the structural formula: Ph₂MeSiOSiMe₂C₃H₆Si(OMe)₃ was obtained as the target product (yield: 98.9%).

### Synthesis Example 18

With the exception of using 20 g (20.0 millimoles) of phenylmethylsiloxane capped at both terminals with vinyl dimethylsiloxy groups represented by the average structural formula: ViMe₂Si(OSiMePh)₆OSiMe₂Vi and 3.9 g (10.0 millimoles) of a compound represented by the structural formula: HMe₂SiOSiMe₂C₁₀H₂₀COOSiMe₃, 23.1 g of silyethylene silicone (surface treatment agent No. 28) with the following average structure was obtained as a clear, colorless liquid in the same manner as in Synthesis Example 9 (yield: 99.7%). (Me₂ViSiO)_{1.5}(Me₂SiO(C₂H₄SiMe₂OSiMe₂C₁₀H₂₀COOH)_{0.5}(PhMeSiO)₆

### <Surface Treatment Agent Nos. 1 to 28 Used in the Practical Examples and Comparative Examples>

In addition to the surface treatment agent Nos. 1 to 9 and 20 to 28 obtained in the synthesis examples described above, the compounds used as the surface treatment agents in the present invention and the structures thereof are shown in the following Tables 2 and 3. These compounds are not only obtained in the synthesis examples described above, but are also commercially available. In each of the structural formulas shown in the following tables, Me₃SiO groups (or Me₃Si groups) are notated as “M”, Me₂SiO groups are notated as “D”, MeHSiO groups are notated as “D^{H}”, and units in which a methyl group in “M” or “D” is modified by any substituent (R) are notated as M^{R} or D^{R}. Similarly, units in which two methyl groups in “M” or “D” are modified by other substituents (R) are notated as M^{R2} or D^{R2}. Treatment agent Nos. 18 and 19 are compounds used in the comparative examples.

TABLE 2

| | | | Number of | | |
|---|---|---|---|---|---|
| | | | silicon | | |
| | | | atoms | Reactive | |
| | | Functional group | excluding | functional | Refractive |
| No. | Structural formula | (-ZQ) | —Si(OMe)₃ | groups | index |
| 1 | M^{Vi}D^{Ph}₂₅—SiMe₂—C₂H₄—SiMe₂ | —C₂H₄—Si(OMe)₃ | 29 | Vi group | 1.5360 |
| | —O—SiMe₂—M^{ZQ} | | | | |
| 2 | M^{Vi}D^{Ph}₁₃D^{Ph2}₁₃—SiMe₂—C₂H₄— | —C₂H₄—Si(OMe)₃ | 30 | Vi group | 1.5760 |
| | SiMe₂—O—SiMe₂—M^{ZQ} | | | | |
| 3 | M^{Vi}D^{Ph}₆—SiMe₂—C₂H₄—SiMe₂— | —C₂H₄—Si(OMe)₃ | 10 | Vi group | 1.5012 |
| | O—SiMe₂—M^{ZQ} | | | | |
| 4 | M^{Ph2}D^{Ph}₂₃D^{Vi}D^{ZQ}M^{Ph2} | —C₂H₄—SiMe₂—O— | 29 | Vi group | 1.5420 |
| | | SiMe₂—C₂H₄—Si(OMe)₃ | | | |
| 5 | M^{Ph2}D^{Ph}₂₁D^{Vi}₂—SiMe(—C₂H₄—S | —C₂H₄—SiMe₂—O— | 30 | Vi group | 1.5387 |
| | iMe₂—D M^{Ph2})-0-D^{ZQ}M^{Ph2} | SiMe₂—C₂H₄—Si(OMe)₃ | | | |
| 6 | M^{Ph2}D^{Ph}₂₂D^{Vi}₂D^{ZQ}M^{Ph2} | —C₂H₄—SiMe₂—O— | 29 | Vi group | 1.5395 |
| | | SiMe₂—C₂H₄—Si(OMe)₃ | | | |
| 7 | M^{Ph2}D^{Ph}₄₇D^{Vi}₂D^{ZQ}M^{Ph2} | —C₂H₄—SiMe₂—O— | 54 | Vi group | 1.5450 |
| | | SiMe₂—C₂H₄—Si(OMe)₃ | | | |
| 8 | M^{Ph2}D^{Ph}₁₀D^{Vi}₂D^{ZQ}M^{Ph2} | —C₂H₄—SiMe₂—O— | 17 | Vi group | 1.5314 |
| | | SiMe₂—C₂H₄—Si(OMe)₃ | | | |
| 9 | M^{Vi}D^{Ph}₂₅—SiMe₂—C₂H₄—DM^{ZQ} | —C₁₀H₂₀COOH | 29 | Vi group | 1.5360 |
| 10 | MD^{ZQ}M | —C₁₀H₂₀COOH | 3 | — | — |
| 11 | MD₂₀₀M^{ZQ} | —C₁₀H₂₀COOH | 202 | — | — |
| 12 | MD₁₀₀M^{ZQ} | —C₁₀H₂₀COOH | 102 | — | — |
| 13 | MD₅₀M^{ZQ} | —C₁₀H₂₀COOH | 52 | — | — |
| 14 | MD^{C12H25}₂₁D^{C14H29}₂₁D^{ZQ}₄M | —C₁₀H₂₀COOH | 48 | — | — |
| 15 | MD^{ZQ}₄₅M | —C₁₀H₂₀COOH | 47 | — | — |
| 16 | MD₄₅D^{ZQ}₂M | —C₃H₆(C₂H₄O)₁₀H | 49 | — | — |
| 17 | MD₂₆D^{ZQ}D^{C2H4Si(OSiMe3)3}₂D^{C12} | —C₃H₆O(CH₂CH(OH)C | 35 | — | — |
| | ^{H25}₂M | H₂O)₂H | | | |
| 18 | CH₂═CH(CH₂)₈—COOH | — | — | — | — |
| 19 | MeSiPh₂OH | — | 1 | — | — |

TABLE 3

| | | | Number of | | | |
|---|---|---|---|---|---|---|
| | | | silicon | | | |
| | | | atoms | | Reactive | |
| | | Functional group | excluding | | functional | Refractive |
| No. | Structural formula | (-ZQ) | —Si(OMe)3 | | groups | index |
| 20 | (Me₂ViSiO)ₓ(Me₂D^{ZQ}SiO)_{y}(P | —C₂H₄—SiMe₂—O— | 15 | (*) | Vi group | 1.5159 |
| | hSiO)₃, X = y = 0.5 | SiMe₂—C₂H₄—Si(OMe)₃ | | | | |
| 21 | (Me₂ViSiO)ₓ(Me₂D^{ZQ}SiO)_{y}(N | —C₂H₄—SiMe₂—O— | 10 | (*) | Vi group | 1.5265 |
| | aphSiO)₃, X = y = 1 | SiMe₂—C₂H₄—Si(OMe)₃ | | | | |
| 22 | ((Me₂ViSiO)ₓ(Me₂D^{ZQ}SiO)_{y}( | —C₂H₄—SiMe₂—O— | 13.5 | (*) | Vi group | 1.5328 |
| | PhSiO)₃, X = 0.75, y = 0.25 | SiMe₂—C₂H₄—Si(OMe)₃ | | | | |
| 23 | (Me₂ViSiO)ₓ(Me₂D^{ZQ}SiO)_{y}(P | —C₂H₄—SiMe₂—O— | 12.375 | (*) | Vi group | 1.5363 |
| | hSiO)₃, X = 0.875, y = 0.125 | SiMe₂—C₂H₄—Si(OMe)₃ | | | | |
| 24 | (Me₂ViSiO)ₓ(Me₂D^{ZQ}SiO)_{y}(P | —C₂H₄—SiMe₂—O— | 12.75 | (*) | Vi group | 1.5337 |
| | hSiO)₃, X = 0.875, y = 0.125 | SiMe₂—C₁₀H₂₀COOH | | | | |

| | | | | | |
|---|---|---|---|---|---|
| 25 | Ph₂MeSiOSiMe₂M^{ZQ} | —C₁₀H₂₀COOH | 3 | — | 1.5037 |
| 26 | Ph₃SiOSiMe₂M^{ZQ} | —C₁₀H₂₀COOH | 3 | — | 1.5294 |
| 27 | Ph₂MeSiOSiMe₂M^{ZQ} | —C₃H₆—Si(OMe)₃ | 2 | — | 1.4991 |
| 28 | M^{Vi}_{1.5}D^{Ph}₆—(SiMe₂—C₂H₄—DM^{ZQ})_{0.5} | —C₁₀H₂₀COOH | 9 | Vi group | 1.5122 |

(*) The number of silicon atoms in one molecule excluding —Si(OMe)₃ is a value calculated based on the number average molecular weight confirmed using NMR. The structural formulas are compositional formulas of each siloxane unit constituting the resin-like molecules confirmed using NMR.

### Practical Examples 1 to 14 and Comparative Examples 1 and 2

In Practical Examples 1 to 14 and Comparative Example 1 described below, the respective dispersions were obtained by performing wet treatment on metal oxide microparticles (barium titanate or titanium oxide) using the respective surface treatment agents. In Practical Examples 1 to 14 and Comparative Example 1, the definitions of the average particle size and the transformation rate are as follows.

### <Average Particle Size>

The average particle size of the metal oxide microparticles in a dispersion is the cumulant average particle size measured using a Zeta-potential particle size measurement system ELSZ-2 (manufactured by Otsuka Electronics Co., Ltd.).

### <Transformation Rate>

The obtained metal oxide microparticle solution was left to stand for 24 hours at room temperature to precipitate undispersed coarse particles. The coarse particles were separated from the dispersion using decantation and a membrane filter with a pore size of 0.2 μm, and the coarse particles were dried. The mass of the dried coarse particles that were ultimately obtained was measured, and the transformation rate was calculated using the following formula. Cases in which no coarse particles were generated were evaluated as having a “transformation rate of 100%”.

Transformation rate=[mass of barium titanate particles used in dispersion−mass of dried coarse particles]/mass of barium titanate particles used in dispersion×100(%)

### Practical Example 1

First, 3 g of barium titanate with a primary particle size of 20 nm, 1.2 g of surface treatment agent No. 1, and 30 g of toluene were mixed in a beaker. The tip of an ultrasonic dispersion device (ultrasonic homogenizer, model No. US-300T, manufactured by Nippon Seiki Co., Ltd.) with an output of 300 W was immersed in this mixture, and the beaker was cooled on ice and irradiated with ultrasonic waves for 30 minutes while ensuring that the liquid temperature did not exceed 40° C. to obtain dispersion 1. When the resulting barium titanate dispersion was measured with a particle size measuring device using a dynamic light scattering method, the cumulant average particle size was 99.5 nm. (Transformation rate: 100%)

### Practical Example 2

First, 36 g of barium titanate with a primary particle size of 20 nm, 20 g of surface treatment agent No. 1, and 360 g of toluene were mixed and stirred using a bead mill filled with 30 μm beads to obtain dispersion 2. When the resulting barium titanate dispersion was measured with a particle size measuring device using a dynamic light scattering method, the cumulant average particle size was 97 nm. (Transformation rate: 100%)

### Practical Example 3

First, 30 g of barium titanate with a primary particle size of 20 nm, 3.0 g of diphenylmethylsilanol (MeSiPh₂OH), and 16.5 g of toluene were mixed well to form a paste. Next, the toluene was removed at room temperature under reduced pressure, and the mixture was placed in an oven at 150° C. The mixture was then treated by leaving the mixture to stand for 1 hour to obtain barium titanate treated with diphenylmethylsilanol.

Next, 9.9 g of this barium titanate treated with diphenylmethylsilanol, 0.9 g of surface treatment agent No. 1, and 90 g were mixed and treated for 1.5 hours with an ultrasonic dispersion device in the same manner as in Practical Example 1 to obtain dispersion 3 with a cumulant average particle size of 100.9 nm. (Transformation rate: 100%)

### Practical Example 4

First, 3 g of barium titanate with a primary particle size of 20 nm, 1.2 g of surface treatment agent No. 2, and 30 g of toluene were mixed in a beaker. The tip of an ultrasonic dispersion device (same as described above) with an output of 300 W was immersed in this mixture, and the beaker was cooled on ice and irradiated with ultrasonic waves for 30 minutes while ensuring that the liquid temperature did not exceed 40° C. to obtain dispersion 4. When the resulting barium titanate dispersion was measured with a particle size measuring device using a dynamic light scattering method, the cumulant average particle size was 102.8 nm. (Transformation rate: 100%)

### Practical Example 5

First, 9 g of barium titanate with a primary particle size of 20 nm, 1.8 g of surface treatment agent No. 1, and 90 g of toluene were mixed in a beaker. The tip of an ultrasonic dispersion device (same as described above) with an output of 300 W was immersed in this mixture, and the beaker was cooled on ice and irradiated with ultrasonic waves for 90 minutes while ensuring that the liquid temperature did not exceed 40° C. and left to stand for 24 hours to obtain dispersion 5 When the resulting barium titanate dispersion was measured with a particle size measuring device using a dynamic light scattering method, the cumulant average particle size was 96.1 nm. The transformation rate of the resulting barium titanate dispersion was 92.4%.

### Practical Example 6

First, 90 g of barium titanate with a primary particle size of 20 nm, 18 g of surface treatment agent No. 1, and 600 g of toluene were mixed in a beaker. The tip of an ultrasonic dispersion device (nano-level ultrasonic treatment device, model UIP1000hd, manufactured by Hielscher Co., Ltd.) with an output of 1000 W was immersed in this mixture, and the beaker was cooled using a coolant circulation system. After the beaker was irradiated with ultrasonic waves for 120 minutes while ensuring that the liquid temperature did not exceed 40° C. and was left to stand for 24 hours, the coarse particles were removed to obtain dispersion 6. When the resulting barium titanate dispersion was measured with a particle size measuring device using a dynamic light scattering method, the cumulant average particle size was 112.8 nm. The transformation rate of the resulting barium titanate dispersion was 95.0%.

### Practical Example 7

First, 9 g of barium titanate with a primary particle size of 20 nm, 1.8 g of surface treatment agent No. 9, and 90 g of toluene were mixed in a beaker. The tip of an ultrasonic dispersion device (same as described above) with an output of 300 W was immersed in this mixture, and the beaker was cooled on ice and irradiated with ultrasonic waves for 90 minutes while ensuring that the liquid temperature did not exceed 40° C. After the beaker was left to stand for 24 hours, the coarse particles were removed to obtain dispersion 7. When the resulting barium titanate dispersion was measured with a particle size measuring device using a dynamic light scattering method, the cumulant average particle size was 94.3 nm. The transformation rate of the resulting barium titanate dispersion was 95.3%.

### Practical Examples 8 to 12

Barium titanate dispersions 8 to 12 were obtained in the same manner as in Practical Example 5 with the exception of using 1.8 of each of the surface treatment agent Nos. 4 to 8 instead of surface treatment agent No. 1. The transformation rates (%) and cumulant average particle sizes are shown in the following Table 4.

TABLE 4

| | Practical | Practical | Practical | Practical | Practical |
|---|---|---|---|---|---|
| | Example 8 | Example 9 | Example 10 | Example 11 | Example 12 |
| | (dispersion | (dispersion | (dispersion | (dispersion | (dispersion |
| | liquid 8) | liquid 9) | liquid 10) | liquid 11) | liquid 12) |
| Surface | 4 | 5 | 6 | 7 | 8 |
| treatment | | | | | |
| agent No. | | | | | |
| Transformation | 94.3 | 92 | 92.7 | 93.7 | 93.1 |
| rate (%) | | | | | |
| Cumulant | 92.9 | 95.1 | 89 | 100.7 | 87.8 |
| average | | | | | |
| particle size | | | | | |
| (nm) | | | | | |

### Practical Example 13

First, 90 g of barium titanate with a primary particle size of 20 nm, 18 g of surface treatment agent No. 6, and 600 g of toluene were mixed in a beaker. The tip of an ultrasonic dispersion device (same as described above) with an output of 1000 W was immersed in this mixture, and the beaker was cooled on ice and irradiated with ultrasonic waves for 180 minutes while ensuring that the liquid temperature did not exceed 40° C. After the beaker was left to stand for 24 hours, the coarse particles were removed to obtain dispersion 13. When the resulting barium titanate dispersion was measured with a particle size measuring device using a dynamic light scattering method, the cumulant average particle size was 97 nm. The transformation rate of the resulting barium titanate dispersion was 97.3%.

### Practical Examples 14 to 18

Barium titanate dispersions 14 to 18 were obtained in the same manner as in Practical Example 5 with the exception of using 1.8 of each of the surface treatment agents shown in the following table instead of surface treatment agent No. 1. The transformation rates (%) and cumulant average particle sizes are shown in the following Table 5.

TABLE 5

| | Practical | Practical | Practical | Practical | Practical |
|---|---|---|---|---|---|
| | Example 14 | Example 15 | Example 16 | Example 17 | Example 18 |
| | (dispersion | (dispersion | (dispersion | (dispersion | (dispersion |
| | liquid 14) | liquid 15) | liquid 15) | liquid 17) | liquid 18) |
| Surface | 11 | 12 | 14 | 17 | 18 |
| treatment | | | | | |
| agent No. | | | | | |
| Transformation | 80.6 | 92.9 | 94.8 | 78.2 | 93.9 |
| rate (%) | | | | | |
| Cumulant | 122.0 | 103.3 | 106.3 | 114.8 | 103.8 |
| average | | | | | |
| particle size | | | | | |
| (nm) | | | | | |

### Comparative Example 1

Dispersion 19 was obtained in the same manner as in Practical Example 5 with the exception of using 1.8 g of surface treatment agent No. 18 (CH₂═CH(CH₂)₈—COOH) instead of surface treatment agent No. 1. However, this dispersion was unstable, and when left to stand at room temperature, the barium titanate precipitated and separated from the solution within one hour.

### Comparative Example 2

Dispersion 20 was obtained in the same manner as in Practical Example 1 with the exception of using 1.2 g of surface treatment agent No. 19 (diphenylmethylsilanol) instead of surface treatment agent No. 1. However, this dispersion was unstable, and when left to stand at room temperature, the barium titanate precipitated and separated from the solution within one hour.

### Practical Example 19

First, 6 g of titanium oxide with a primary particle size of 35 nm, 1.8 g of surface treatment agent No. 1, and 90 g of toluene were mixed in a beaker. The tip of an ultrasonic dispersion device (same as described above) with an output of 300 W was immersed in this mixture, and the beaker was cooled on ice and irradiated with ultrasonic waves for 90 minutes while ensuring that the liquid temperature did not exceed 40° C. After the beaker was left to stand for 24 hours, the coarse particles were removed to obtain dispersion 21. When the resulting titanium oxide dispersion was measured with a particle size measuring device using a dynamic light scattering method, the cumulant average particle size was 138.0 nm. The transformation rate of the resulting titanium oxide dispersion was 99.4%.

### Practical Examples 20 to 39

### Evaluation of the Curable Organopolysiloxane Composition and the Cured Product

The barium titanate dispersions [3, 4, 8, and 9] prepared in Practical Examples 3, 4, 8, and 9 were mixed with vinyl functional polyorganosiloxane and SiH functional polyorganosiloxane in accordance with the compositions shown in Tables 6 to 9 so that the content of barium titanate was a prescribed amount. Next, a 1,3-divinyltetramethyl disiloxane platinum complex was mixed at an amount in which the platinum metal was 2 ppm with respect to the solid content in weight units so as to prepare a solution of a curable organopolysiloxane composition. This solution of the curable organopolysiloxane composition was dripped onto a glass plate and dried for one hour at 70° C. After the solvent was removed, the mixture was heated for 2 hours at 150° C. to obtain a cured product.

The makeup of the cured organopolysiloxane compositions and the evaluation results of the cured products are shown in Tables 4 to 7. The compositions in the table are expressed as the mass % of the curable composition (solid content) excluding the toluene in the dispersions. The SiH/Vi ratio in the table represents the number of moles of silicon-bonded hydrogen atoms in the SiH functional polyorganosiloxane with respect to a total of 1 mole of the dispersion and vinyl groups in the vinyl functional polyorganosiloxane in the curable organopolysiloxane composition.

### <Refractive Index of the Cured Product>

The refractive index of the cured product of the curable silicone composition formed with the method described above was measured using a prism coupler method. A 632.8 nm (approximately 633 nm) laser light source was used for measurements.

### <Transmittance of Cured Product>

Unless specified otherwise, the transmittance of the cured product expresses the transmittance of light with a wavelength of 580 nm at a thickness of 10 μm.

In addition, the appearance and strength of each cured product was evaluated in accordance with the criteria shown below.

“Appearance”: The presence or absence of cracking (cracks) in the cured product was evaluated visually.

“Strength”: The presence or absence of tack was evaluated by touching the surface of the cured product with a finger.

TABLE 6

| | | | Practical Examples | | | | | | |
|---|---|---|---|---|---|---|---|---|---|
| | | | (Practical examples using “dispersion 3”) | | | | | | |
| | | | 20 | 21 | 22 | 23 | 24 | 25 | 26 |
| Composition | (ViMe₂SiO_{1/2})₂₅(PhSiO_{3/2})₇₅ | | — | — | — | 29.5 | 23.5 | 15 | 16 |
| % by mass | (ViPhMeSiO_{1/2})₄₀(NpSiO_{3/2})₆₀ | | 28.5 | 22.5 | 15 | — | — | — | — |
| (Solid content | (ViMe₂SiO(PhMesiO)₂₀SiMe₂ | | — | — | 11 | — | — | 12 | 20.5 |
| conversion | Vi | | | | | | | | |
| excluding | HMe₂SiO(Ph₂SiO)SiMe₂H | | 11.5 | — | — | 10.5 | — | — | — |
| toluene) | HMe₂SiO(Ph₂SiO)_{2.5}SiMe₂H | | — | 17.5 | 14 | — | 16.5 | 13 | — |
| | MeSiPh₂OH | | 5 | 5 | 5 | 5 | 5 | 5 | 5 |
| | Surface treatment agent | | 5 | 5 | 5 | 5 | 5 | 5 | 5 |
| | No. 1 | | | | | | | | |
| | Barium titanate | | 50 | 50 | 50 | 50 | 50 | 50 | 50 |
| SiH/Vi ratio | | | 1.0 | 1.0 | 1.0 | 1.0 | 1.0 | 1.0 | 1.0 |
| Characteristics | Refractive index (633 nm) | | 1.719 | 1.687 | 1.642 | 1.668 | 1.671 | 1.599 | 1.645 |
| of the cured | Appearance/ | Cracks | No | No | No | No | No | No | No |
| product | strength | Tack | No | No | No | No | No | No | No |

TABLE 7

| | | | Practical Examples | | | |
|---|---|---|---|---|---|---|
| | | | (Practical examples | | | |
| | | | using “dispersion 3”) | | | |
| | | | 27 | 28 | 29 | 30 |
| Composition | (ViMe₂SiO_{1/2})₂₅(PhSiO_{3/2})₇₅ | | — | 20 | — | 39 |
| % by mass | (ViPhMeSiO_{1/2})₄₀(NpSiO_{3/2})₆₀ | | 20 | — | 37 | — |
| (Solid content conversion | (ViMe₂SiO(PhMeSiO)₂₀SiMe₂ | | 14 | 15.5 | — | — |
| excluding toluene) | Vi | | | | | |
| | HMe₂SiO(Ph₂SiO)SiMe₂H | | — | — | — | — |
| | HMe₂SiO(Ph₂SiO)_{2.5}SiMe₂H | | 18 | 16.5 | 27 | 25 |
| | MeSiPh₂OH | | 4 | 4 | 3 | 3 |
| | Surface treatment agent | | 4 | 4 | 3 | 3 |
| | No. 1 | | | | | |
| | Barium titanate | | 40 | 40 | 30 | 30 |
| SiH/Vi ratio | | | 1.0 | 1.0 | 1.0 | 1.0 |
| Characteristics | Refractive index (633 nm) | | 1.617 | 1.586 | 1.650 | 1.610 |
| of the cured | Appearance/ | Cracks | No | No | No | No |
| product | strength | Tack | No | No | No | No |

| | | | | |
|---|---|---|---|---|
| Transmittance (%) | 82 | — | 86 | — |

TABLE 8

| | | | Practical Examples | | |
|---|---|---|---|---|---|
| | | | (Practical examples | | |
| | | | using “dispersion 5”) | | |
| | | | 31 | 32 | 33 |
| Composition | (ViMe₂SiO_{1/2})₂₅(PhSiO_{3/2})₇₅ | | — | — | 23.5 |
| % by mass | (ViPhMeSiO_{1/2})₄₀(NpSiO_{3/2})₆₀ | | 22 | 28 | — |
| (Solid content conversion | HMe₂SiO(Ph₂SiO)SiMe₂H | | — | 12 | — |
| excluding toluene) | HMe₂SiO(Ph₂SiO)_{2.5}SiMe₂H | | 18 | — | 16.5 |
| | Surface treatment agent | | 10 | 10 | 10 |
| | No. 1 | | | | |
| | Barium titanate | | 50 | 50 | 50 |
| SiH/Vi ratio | | | 1.0 | 1.0 | 1.0 |
| Characteristics of the | Refractive index (633 nm) | | 1.680 | 1.691 | 1.667 |
| cured product | Appearance/ | Cracks | No | No | No |
| | strength | Tack | No | No | No |

| | | | |
|---|---|---|---|
| Transmittance (%) | 89 | 91 | 82 |

TABLE 9

| | | | Practical Examples | | | | | |
|---|---|---|---|---|---|---|---|---|
| | | | (Practical examples using | | | | | |
| | | | “dispersion 8” or “dispersion 9”) | | | | | |
| | | | 34 | 35 | 36 | 37 | 38 | 39 |
| Composition | (ViMe₂SiO_{1/2})₂₅(PhSiO_{3/2})₇₅ | | — | — | 23.5 | — | — | 23.5 |
| % by mass | (ViPhMeSiO_{1/2})₄₀(NpSiO_{3/2})₆₀ | | 22.5 | 28.5 | — | 22 | 28 | — |
| (Solid content | HMe₂SiO(Ph₂SiO)SiMe₂H | | — | 11.5 | — | | 12 | — |
| conversion | HMe₂SiO(Ph₂SiO)_{2.5}SiMe₂H | | 17.5 | — | 16.5 | 18 | — | 16.5 |
| excluding | Surface treatment agent No. 4 | | 10 | 10 | 10 | — | — | — |
| toluene) | Surface treatment agent No. 5 | | — | — | — | 10 | 10 | 10 |
| | Barium titanate | | 50 | 50 | 50 | 50 | 50 | 50 |
| SiH/Vi ratio | | | 1.0 | 1.0 | 1.0 | 1.0 | 1.0 | 1.0 |
| Characteristics | Refractive index (633 nm) | | 1.611 | 1.704 | 1.606 | 1.654 | 1.708 | 1.647 |
| of the cured | Appearance/ | Cracks | No | No | No | No | No | No |
| product | strength | Tack | No | No | No | No | No | No |

### Practical Examples 40 to 41

### Evaluation of the Curable Organopolysiloxane Composition and the Cured Product

The titanium oxide dispersion [19] prepared in Practical Example 19 was mixed with vinyl functional polyorganosiloxane and SiH functional polyorganosiloxane in accordance with the compositions shown in Table 10 so that the content of titanium oxide was a prescribed amount. Next, a 1,3-divinyltetramethyl disiloxane platinum complex was mixed at an amount in which the platinum metal was 2 ppm with respect to the solid content in weight units so as to prepare a solution of a curable organopolysiloxane composition.

This solution of the curable organopolysiloxane composition was dripped onto a glass plate and dried for one hour at 70° C. After the solvent was removed, the mixture was heated for 2 hours at 150° C. to obtain a cured product.

The makeup of the cured organopolysiloxane compositions and the evaluation results of the cured products are shown in Table 8. The compositions in the table are expressed as the mass % of the curable composition (solid content) excluding the toluene in the dispersions. The SiH/Vi ratio in the table represents the number of moles of silicon-bonded hydrogen atoms in the SiH functional polyorganosiloxane with respect to a total of 1 mole of the dispersion and vinyl groups in the vinyl functional polyorganosiloxane in the curable organopolysiloxane composition.

The evaluation criteria for each characteristic are the same as in Practical Examples 20 to 39.

TABLE 10

| | | | Practical Examples | |
|---|---|---|---|---|
| | | | (Practical examples using | |
| | | | “dispersion 23”) | |
| | | | 40 | 41 |
| Composition | (ViMe₂SiO_{1/2})₂₅(PhSiO_{3/2})₇₅ | | — | 33.7 |
| % by mass | (ViPhMeSiO_{1/2})₄₀(NpSiO_{3/2})₆₀ | | 31.2 | — |
| (Solid content | HMe₂SiO(Ph₂SiO)SiMe₂H | | 25.5 | 23 |
| conversion | Surface treatment agent No. 1 | | 10 | 10 |
| excluding toluene) | Titanium oxide | | 33.3 | 33.3 |
| SiH/Vi ratio | | | 1.0 | 1.0 |
| Character- | Refractive index (633 nm) | | 1.688 | 1.680 |
| istics of the | Appearance/ | Cracks | No | No |
| cured product | strength | Tack | No | No |

### Practical Example 42

### Evaluation of the Curable Organopolysiloxane Composition and the Cured Product

A zirconium oxide dispersion (OZ—S30K manufactured by Nissan Chemical Industries, methyl ethyl ketone solution containing 30% zirconium oxide) and surface treatment agent No. 1 were mixed with the compositions shown in Table 11. Next, a vinyl functional polyorganosiloxane and an SiH functional polyorganosiloxane were mixed. A 1,3-divinyltetramethyl disiloxane platinum complex was mixed at an amount in which the platinum metal was 2 ppm with respect to the solid content in weight units so as to prepare a solution of a curable organopolysiloxane composition. This solution of the curable organopolysiloxane composition was dripped onto a glass plate and dried for one hour at 70° C. After the solvent was removed, the mixture was heated for 2 hours at 150° C. to obtain a cured product.

The compositions in the table are expressed as the mass % of the curable composition (solid content) excluding the toluene and methyl ethyl ketone in each dispersion.

The makeup of the cured organopolysiloxane compositions and the evaluation results of the cured products are shown in Table 9.

The SiH/Vi ratio in the table represents the number of moles of silicon-bonded hydrogen atoms in the SiH functional polyorganosiloxane with respect to a total of 1 mole of the dispersion and vinyl groups in the vinyl functional polyorganosiloxane in the curable organopolysiloxane composition. The evaluation criteria for each characteristic are the same as in Practical Examples 20 to 39.

TABLE 11

| | | | Practical Examples |
|---|---|---|---|
| | | | (Practical example using |
| | | | zirconium oxide) |
| | | | 42 |
| Composition | (ViPhMeSiO_{1/2})₄₀(NpSiO_{3/2})₆₀ | | 22 |
| % by mass | HMe₂SiO(Ph₂SiO)SiMe₂H | | 18 |
| (solid content | Surface treatment agent No. 1 | | 10 |
| conversion excluding | Zirconium oxide | | 50 |
| the solvent) | * “OZ-S30K” manufactured by Nissan | | |
| | Chemical Industries | | |
| SiH/Vi ratio | | | 1.0 |
| Titanium oxide (% by mass) | | | 50.0 |
| Character- | Refractive index (633 nm) | | 1.637 |
| istics of the | Appearance/ | Cracks | No |
| cured product | strength | Tack | No |

### Comparative Example 3

### Evaluation of the Curable Organopolysiloxane Composition and the Cured Product

A cured product was obtained in accordance with the same procedure as in Practical Example 31 with the exception of changing dispersion 5 of Practical Example 31 to dispersion 19 prepared in Comparative Example 1.

The makeup of the cured organopolysiloxane compositions and the evaluation results of the cured products are shown in Table 12. The SiH/Vi ratio in the table represents the number of moles of silicon-bonded hydrogen atoms in the SiH functional polyorganosiloxane with respect to a total of 1 mole of the dispersion and vinyl groups in the vinyl functional polyorganosiloxane in the curable organopolysiloxane composition.

The evaluation criteria for each characteristic are the same as in Practical Examples 20 to 39.

TABLE 12

| | | | Comparative Examples |
|---|---|---|---|
| | | | (Comparative example using |
| | | | “dispersion 19”) |
| | | | 3 |
| Composition | (ViMe₂SiO_{1/2})₂₅(PhSiO_{3/2})₇₅ | | — |
| % by mass | (ViPhMeSiO_{1/2})₄₀(NpSiO_{3/2})₆₀ | | 22 |
| (Solid content conversion | HMe₂SiO(Ph₂SiO)SiMe₂H | | — |
| excluding toluene) | HMe₂SiO(Ph₂SiO)_{2.5}SiMe₂H | | 18 |
| | Surface treatment agent No. 18 | | 10 |
| | Barium titanate | | 50 |
| SiH/Vi ratio | | | 1.0 |
| Characteristics of the cured | Refractive index (633 nm) | | 1.673 |
| product | Appearance/ | Cracks | No |
| | strength | Tack | No |

| | |
|---|---|
| Transmittance (%) | 67 |

When treatment was performed using 10-undecenoic acid (CH₂═CH(CH₂)₈—COOH), the transmittance of the cured product dramatically dropped in comparison to Practical Example 31. In addition, the refractive index of the cured product also dropped.

### Comparative Examples 4 and 5

### Evaluation of the Curable Organopolysiloxane Composition and the Cured Product

Vinyl functional polyorganosiloxane and SiH functional polyorganosiloxane were mixed in accordance with the compositions shown in Table 12. Next, a 1,3-divinyltetramethyl disiloxane platinum complex was mixed at an amount in which the platinum metal was 2 ppm with respect to the solid content in weight units so as to prepare a solution of a curable organopolysiloxane composition. In contrast to the practical examples, neither metal oxide microparticles nor the surface treatment agent for an optical material of the present invention were used. This solution of the curable organopolysiloxane composition was dripped onto a glass plate and dried for one hour at 70° C. After the solvent was removed, the mixture was heated for 2 hours at 150° C. to obtain a cured product.

The makeup of the cured organopolysiloxane compositions and the evaluation results of the cured products are shown in Table 13. The SiH/Vi ratio in the table represents the number of moles of silicon-bonded hydrogen atoms in the SiH functional polyorganosiloxane with respect to a total of 1 mole of the dispersion and vinyl groups in the vinyl functional polyorganosiloxane in the curable organopolysiloxane composition.

The evaluation criteria for each characteristic are the same as in Practical Examples 20 to 39.

TABLE 13

| | | | Comparative Examples | |
|---|---|---|---|---|
| | | | 4 | 5 |
| Composition | (ViMe₂SiO_{1/2})₂₅(PhSiO_{3/2})₇₅ | | — | 58.8 |
| % by | (ViPhMeSiO_{1/2})₄₀(NpSiO_{3/2})₆₀ | | 56.3 | — |
| mass | HMe₂SiO(Ph₂SiO)SiMe₂H | | 43.8 | 41.3 |
| SiH/Vi ratio | | | 1.0 | 1.1 |
| Metal oxide particles (% by mass) | | | 0 | 0 |
| Character- | Refractive index (633 nm) | | 1.606 | 1.571 |
| istics of | Appearance/ | Cracks | No | No |
| the cured | strength | Tack | No | No |
| product | | | | |

Comparative Example 4 is a case in which dispersion 4 was removed from the composition of Practical Example 21, but the refractive index decreased by 0.081, and effects on the refractive index of the barium titanate dispersion were confirmed. In Comparative Example 5, it was not possible to realize a high refractive index of at least 1.60 in the cured product.

### Synthesis Example 1 of Dispersible Titanium Oxide Particles

Surface treatment agent No. 10, titanium tetrachloride, and distilled water are added to a 1 L 3-neck flask provided with a reflux condenser, a thermometer, and an airtight stopper under a nitrogen airflow. The reaction mixture is heated to a reaction temperature of 160° C. and then heated for 4 hours while being refluxed. The reaction mixture is cooled to room temperature and placed in a centrifugation container. After acetone is added, the mixture is centrifuged. The transparent supernatant is discarded, and the remaining reaction mixture is added to this centrifugation container. After acetone is added to a volume of 600 mL, the mixture is centrifuged. The resulting solid is washed twice with acetone and then dried overnight in a vacuum produced by a rotary slide valve oil pump. The resulting TiO2 particles demonstrate improved dispersibility.

### Synthesis Examples 2 and 3 of Dispersible Titanium Oxide Particles

TiO2 particles can also be synthesized using surface treatment agent No. 13 or 15 instead of surface treatment agent No. 10 in Synthesis Example 1 described above.

### Synthesis Example of Dispersible Iron Nanoparticles

An iron acetate (II) aqueous solution serving as a raw material, a reducer (formic acid), and surface treatment agent No. 1 are added to a pressure-resistant container. This is heated to 400° C. and reacted. After the reaction, iron nanoparticles are contained in the resulting product. The reaction mixture is cooled to room temperature and placed in a centrifugation container. After acetone is added, the mixture is centrifuged. The transparent supernatant is discarded, and the remaining reaction mixture is added to this centrifugation container. After acetone is further added, the mixture is centrifuged. The resulting solid is washed twice with acetone and then dried overnight in a vacuum produced by a rotary slide valve oil pump. The resulting iron nanoparticles demonstrate improved dispersibility.

### Synthesis Example of a Barium Titanate Dispersion by a Sol Gel Method

A barium alcoholate solution is prepared by adding splintered barium metal to a mixed solvent of methanol and methoxyethanol and stirring the mixture for 2 hours at room temperature. An amount of tetraisopropoxytitanate equimolar to the barium metal is added to this barium alcoholate, and the entire mixture is cooled to −50° C. with a dry ice/acetone bath while stirring. A methanol aqueous solution is dripped into this mixture at −30° C., and the solution obtained by stirring is transferred to a glass vial. When this solution is left to stand until the solution returns to room temperature, the solution increases its viscosity to be a clear, colorless, uniform sol. When the mixture is left to stand for 24 hours in a 40° C. oven, crystallization progresses and the crystals shrink so that alcohols and excess water are discharged to the outside of the crystals. The liquid content is removed by decantation, and methoxyethanol is newly added. The mixture is placed in an ultrasonic washing device and irradiated with ultrasonic waves for 15 hours at a temperature of at most 40° C. to obtain a methoxyethanol dispersion of barium titanate as a translucent liquid. Next, surface treatment is performed on the barium titanate microparticles formed in the liquid phase by adding a carboxy-modified trisiloxane (=surface treatment agent No. 10) represented by Me₃SiOSiMe(C₁₀H₂₀COOH)OSiMe₃.

### Practical Examples 43 to 47

Barium titanate dispersions 20 to 24 were obtained in the same manner as in Practical Example 5 with the exception of using 4.5 g of each of the surface treatment agent Nos. 20 to 24 instead of 4.5 g of barium titanate and surface treatment agent No. 1. The transformation rates (%) and cumulant average particle sizes are shown in the following Table 14.

TABLE 14

| | Practical | Practical | Practical | Practical | Practical |
|---|---|---|---|---|---|
| | Example 43 | Example 44 | Example 45 | Example 46 | Example 47 |
| | (dispersion | (dispersion | (dispersion | (dispersion | (dispersion |
| | liquid 20) | liquid 21) | liquid 22) | liquid 23) | liquid 24) |
| Surface | 20 | 21 | 22 | 23 | 24 |
| treatment | | | | | |
| agent No. | | | | | |
| Transformation | 90.3 | 87.6 | 97.8 | 96 | 97.3 |
| rate (%) | | | | | |
| Cumulant | 97.8 | 98.8 | 100.5 | 98.7 | 100.3 |
| average | | | | | |
| particle size | | | | | |
| (nm) | | | | | |

### Comparative Example 6

Ultrasonic dispersion treatment was performed in the same manner as in Practical Example 5 with the exception of using 4.5 g of the vinyl functional silicone resin having a vinyl group content of 5.6 wt. % and represented by the compositional formula (Me₂ViSiO)(PhSiO)₃ used as a raw material in Synthesis Example 10 instead of 4.5 g of barium titanate and surface treatment agent No. 1. However, when the dispersion was left to stand, phase separation occurred immediately, and the barium titanate particles were precipitated.

### Practical Example 48

Treatment agent No. 16 was added to an isopropoxyethanol dispersion of barium titanate with a cumulant particle size of 21.0 nm synthesized by a sol gel method so that the weight ratio of barium titanate and treatment agent No. 16 was 1:1. After the low-boiling point matter was removed by heating under reduced pressure, toluene was added at a volume of 9 times the weight of the remaining amount to prepare a 10 wt. % dispersion (dispersion 25). The measured cumulant particle size was 37.4 nm.

### Practical Examples 49 to 58

Ten wt. % toluene dispersions (dispersions 26 to 35) were prepared in the same manner as in Practical Example 48 with the exception of using the combinations and quantities of isopropoxy ethanol dispersions of the barium titanate with the cumulant particle sizes shown in the following

Table 14 and the surface treatment agents shown in the table. The measured values of the cumulant average particle sizes are shown in the following Table 15.

TABLE 15

| | Practical Example No. | | | | | |
|---|---|---|---|---|---|---|
| | 49 | 50 | 51 | 52 | 53 | 54 |
| | (Dispersion No.) | | | | | |
| | (26) | (27) | (28) | (29) | (30) | (31) |
| Cumulant average particle size of barium | 21 | 21 | 23.9 | 23.9 | 23.9 | 23.9 |
| titanate (nm) | | | | | | |
| Surface treatment agent No. 1 | 24 | 24 | 24 | 24 | 24 | 9 |
| Surface treatment agent No. 2 | — | — | 26 | 25 | 25 | 26 |
| Surface treatment agent 1/surface | 1/0/1 | 0.75/0/1 | 1/1/4 | 1/1/4 | 1/1/4 | 1/1/4 |
| treatment agent 2/barium titanate weight | | | | | | |
| ratio | | | | | | |
| Cumulant average particle size (nm) | 37.4 | 89.9 | 31.9 | 32.7 | 38 | 33.4 |

| | Practical Example No. | | | |
|---|---|---|---|---|
| | 55 | 56 | 57 | 58 |
| | (Dispersion No.) | | | |
| | (32) | (33) | (34) | (35) |
| Cumulant average particle size of barium | 22.8 | 33.7 | 23.9 | 23.9 |
| titanate (nm) | | | | |
| Surface treatment agent No. 1 | 25 | 25 | 27 | 27 |
| Surface treatment agent No. 2 | — | — | — | — |
| Surface treatment agent 1/surface | 0.3/0/1 | 0.3/0/1 | 1/0/1 | 0.55/0/1 |
| treatment agent 2/barium titanate weight | | | | |
| ratio | | | | |
| Cumulant average particle size (nm) | 33.7 | 35 | 105.8 | 158.3 |

### Preparation Example 1 of a Silica-Covered Barium Titanate Powder

Ten g of barium titanate having a cumulant average particle size of 35 nm was placed in 170 g of water, and 5.2 g (50.9 millimoles) of concentrated hydrochloric acid was added. Next, barium titanate was dispersed in the hydrochloric acid aqueous solution using an ultrasonic dispersion device. A sodium silicate aqueous solution obtained by dissolving 1.3 g (3.6 millimoles) of sodium silicate represented by the average structural formula: Na₂O_{2.2}SiO₂ 9.3H₂O in 5 g of water while irradiating the solution with ultrasonic waves was gradually dripped into the solution, and a sodium hydroxide aqueous solution obtained by dissolving 1.75 g (43.7 millimoles) of sodium hydroxide in 5 g of water was then gradually dripped into the solution. After it was confirmed that the pH was neutral, the precipitated solid was removed by filtration and washed with water twice. The water content was removed by heating under reduced pressure at 80° C. to obtain 9.2 g of a silica-covered barium titanate powder. The weight ratio of the silica component and the barium titanate was calculated from the loaded weight to be 0.047/1.

### Preparation Example 2 of a Silica-Covered Barium Titanate Powder

A silica-covered barium titanate powder was obtained in the same manner as in Preparation Example 1 of the silica-covered barium titanate powder with the exception of using 2.6 g (7.2 millimoles) of sodium silicate and 1.4 g (36.5 millimoles) of sodium hydroxide. The weight ratio of the silica component and the barium titanate was calculated from the loaded weight to be 0.096/1.

### Example of Covering Barium Nanotitanate with Silica Using a Sol Gel Method

First, 0.19 g (0.9 millimoles) of tetraethoxysilane is added to 20.6 g of a 2.77 wt. % isopropyl cellosolve dispersion of barium titanate having a cumulant average particle size of 10 nm prepared by a sol gel method and then stirred for 12 hours at 40° C. Next, 0.17 g (0.37 millimoles) of surface treatment agent No. 27 is added and further stirred for 12 hours at 40° C. A 10 wt. % toluene dispersion can be obtained by removing the low-boiling point matter while heating under reduced pressure and adding toluene to the residue.

### Preparation Example of a Silica-Coated Barium Titanate Dispersion Using a Bead Mill

A silica-covered barium titanate dispersion treated with surface treatment agent No. 1 can be obtained by mixing 36 g of the silica-covered barium titanate powder obtained in Preparation Example 1 of a silica-covered barium titanate powder, 20 g of surface treatment agent No. 1, and 360 g of toluene and stirring the solution using a bead mill filled with 30 μm beads.

### Preparation Example of a Curable Silicone Composition Using Silica-Covered Barium Titanate

A curable silicone composition having a high refractive index of at least 1.55 can be obtained by mixing the silica-covered barium titanate dispersion obtained above with a condensation-reactive or hydrosilylation-reactive organic silicon compound and curing the mixture. These silicone compositions are suitable as optical materials, particularly as sealants or chip coating materials for optical semiconductor elements.

### Practical Example 59

### Evaluation of the Curable Organopolysiloxane Composition and the Cured Product

Barium titanate dispersion 32 and surface treatment agent No. 28 were mixed in accordance with the composition shown in Table 15. Next, the respective components shown in the table were mixed. A platinum complex of 1,3-divinyltetramethyldisiloxane was poured into a plate made of Teflon (registered trademark) and then left to stand overnight at room temperature so that the platinum metal demonstrated a certain amount of weight units with respect to the solid content. This solution of the curable organopolysiloxane was dripped onto a glass plate and heated for one hour at 170° C. to obtain a cured product.

The compositions in the table are expressed as the mass % of the curable composition (solid content) excluding the toluene and methyl ethyl ketone in each dispersion.

The makeup of the cured organopolysiloxane compositions and the evaluation results of the cured products are shown in Table 16.

The SiH/Vi ratio in the table represents the number of moles of silicon-bonded hydrogen atoms in the SiH functional polyorganosiloxane with respect to a total of 1 mole of the dispersion and vinyl groups in the vinyl functional polyorganosiloxane in the curable organopolysiloxane composition. The evaluation criteria for each characteristic are the same as in Practical Examples 20 to 39.

TABLE 16
Practical Example 59

| Composition | Dispersion 32 (solid content conversion | 39.2 |
|---|---|---|
| % by mass | excluding the solvent) | |
| | Benzoic acid | 3.1 |
| | Surface treatment agent No. 28 | 6.9 |
| | Polyphenylmethylsiloxane capped at both | 31.2 |
| | terminals with PhMeViSiO groups having | |
| | an average degree of polymerization of 6 | |
| | Polyphenylmethylsiloxane capped at both | 15.3 |
| | terminals with Me₂HSiO groups having an | |
| | average degree of polymerization of 6 | |
| | Polysiloxane represented by the average | 4.3 |
| | structural formula (Me₂HSiO)₆(PhSiO)₄ | |
| SiH/Vi ratio | | 1.0 |
| BaTiO₃ (% by mass) | | 30 |
| Characteristics | Refractive index (633 nm) | 1.579 |
| of the cured | Appearance/strength Cracks | No |
| product | Tack | No |

### Practical Examples 60 to 62

A 68.7 wt. % toluene solution of a polysiloxane represented by the average structural formula (PhSiO_{3/2})_{0.41}(PhMeSiO₁₂)_{0.59}, dispersion 32 and a zinc octanoate (in an amount so that the zinc weight was 2000 ppm with respect to the solid content) were mixed in tetrahydrofuran, and the low-boiling point matter was partially removed while heating under reduced pressure to obtain a dispersion with a solid concentration of approximately 20 wt. %. After this mixture was poured into a plate made of Teflon (registered trademark), the mixture was left to stand overnight at room temperature, heated for 2 hours in a 50° C. oven, further heated for 2 hours under reduced pressure at the same temperature, and then returned to normal pressure and heated for 1 hour at 170° C. to cure the mixture. All of the cured products were clear, and the values of the film thickness, transmittance, and refractive index of the cured products are shown in the following Table 17.

TABLE 17

| | Practical | Practical | Practical |
|---|---|---|---|
| | Example | Example | Example |
| | 60 | 61 | 62 |
| Weight ratio of solid content in | 0.54/1 | 0.93/1 | 1.56/1 |
| (PhSiO_{3/2})_{0.41}(PhMeSiO_{1/2})_{0.59}/ | | | |
| dispersion 32 | | | |
| Refractive index (633 nm) | 1.634 | 1.611 | 1.595 |
| Transmittance (580 nm) | 87.1% | 88.5% | 88.0% |
| Transmittance (450 nm) | 81.5% | 85.1% | 84.5% |
| Film thickness (mm) | 0.16 | 0.22 | 0.31 |

### Practical Examples 63 and 64

Surface treatment agent No. 25 was added to NanoUse OZ-30 M (nanozirconia methanol dispersion, particle size: 10 nm) manufactured by Nissan Chemical Industries Co., Ltd., and a 10 wt. % toluene dispersion of zirconia which was surface-treated by the same operation as in Practical Example 48 was obtained. The cumulant average particle size is shown in the following Table 18.

TABLE 18

| | Practical | Practical |
|---|---|---|
| | Example 63 | Example 64 |
| | (dispersion | (dispersion |
| | liquid 36) | liquid 37) |
| Surface treatment agent No. | 25 | 25 |
| Surface treatment agent/zirconia | 0.2/1 | 0.3/1 |
| weight ratio | | |
| Cumulant average particle size (nm) | 112 | 43.2 |

### Practical Example 65

First, 36 g of barium titanate with a primary particle size of 20 nm, 7.85 g of surface treatment agent No. 25, and 360 g of toluene were mixed and stirred using a bead mill filled with 30 μm to obtain dispersion 38. When the resulting barium titanate dispersion was measured with a particle size measuring device using a dynamic light scattering method, the cumulant average particle size was 69 nm. (Transformation rate: 100%)

### Practical Examples 66 to 68

The barium titanate dispersion obtained in Practical Example 2 was used and mixed in accordance with the composition shown in the following Table 19, and a complex catalyst consisting of platinum and 1,3-divinyltetramethyldisiloxane was further added so that the platinum metal concentration was 6.6 ppm of the solid content. This mixture was heated for 2 hours at 150° C. to obtain a curable silicone composition. The evaluation criteria for each characteristic are the same as in Practical Examples 20 to 39.

TABLE 19

| | | | Practical Examples | | |
|---|---|---|---|---|---|
| | | | 66 | 67 | 68 |
| Compo- | (ViMe₂SiO_{1/2})₂₅(PhSiO_{3/2})₇₅ | | 19.4 | 13.3 | 7.3 |
| sition | ViMe₂SiO(PhMeSiO)₂₀SiMe₂Vi | | 24.0 | 17.0 | 10.0 |
| % by mass | HMe₂SiO(Ph₂SiO)SiMe₂H | | 10.0 | 7.5 | 5.0 |
| | Barium titanate dispersion 2 | | 46.7 | 62.2 | 77.8 |
| | obtained in Practical Example 2 | | | | |
| | (excluding the solvent) | | | | |
| SiH/Vi ratio | | | 1.0 | 1.0 | 1.0 |
| BaTiO₃ (% by mass) | | | 30 | 40 | 50 |
| Character- | Refractive index | | 1.600 | 1.616 | 1.642 |
| istics of | (633 nm) | | | | |
| the cured | Appearance/ | Cracks | No | No | No |
| product | strength | Tack | No | No | No |

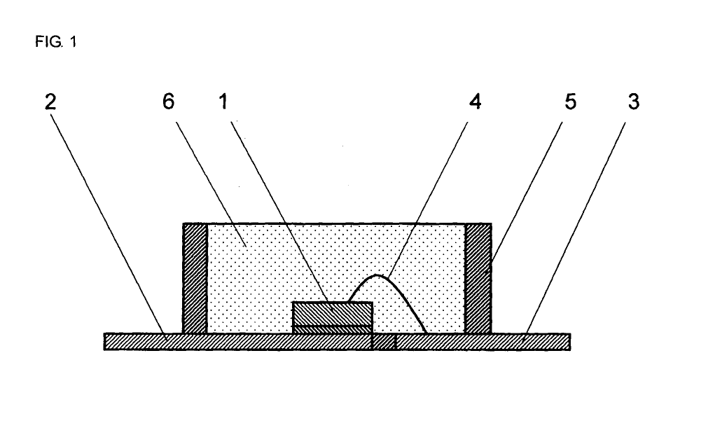

The surface treatment agent for an optical material of the present invention and an optical material consisting of a curable composition containing the surface treatment agent are suitable as a sealant or a chip coating material for an optical semiconductor agent. For example, a cross-sectional view of a surface-mounted LED is illustrated in FIG. 1 as an example of an optical semiconductor element using the surface treatment agent for an optical material according to the present invention.

In the LED illustrated in FIG. 1, an optical semiconductor element 1 is die-bonded to a lead frame 2, and the semiconductor element 1 and a lead frame 3 are wire-bonded by a bonding wire 4. This optical semiconductor element 1 is resin-sealed by a silicone cured product formed by a curable silicone composition containing the surface treatment agent for an optical material of the present invention.

### EXPLANATION OF SYMBOLS

1 light-emitting element
2 lead frame
3 lead frame
4 Bonding wire
5 frame material
6 cured product of a curable silicone composition containing the surface treatment agent for an optical material of the present invention

1. A surface treatment agent for an optical material comprising an organic silicon compound having:
a functional group selected from a highly polar functional group, a hydroxyl group-containing group, a silicon atom-containing hydrolyzable group, or metal salt derivatives thereof bonded to silicon atoms directly or via a functional group with a valency of (n+1), where n is a number equal to 1 or greater, and
having at least one structure in the molecule in which the silicon atoms are bonded to any siloxane unit represented by R¹₃SiO_{1/2}, R¹₂SiO_{2/2}, R¹SiO_{3/2}, and SiO_{4/2}, wherein R¹ is a substituted or unsubstituted monovalent hydrocarbon group, a hydrogen atom, a halogen atom, a hydroxyl group, an alkoxy group, or a functional group selected from a highly polar functional group, a hydroxyl group-containing group, a silicon atom-containing hydrolyzable group, or metal salt derivatives thereof bonded to silicon atoms via a functional group with a valency of (n+1).

2. The surface treatment agent for an optical material according to claim 1, wherein the organic silicon compound has at least one structure represented by the following formula in the molecule and has from 2 to 1,000 silicon atoms in the molecule: 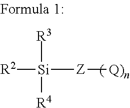
wherein, Z is a direct bond to a silicon atom or a functional group with a valency of (n+1);
n is a number equal to 1 or greater;
Q is a functional group selected from a highly polar functional group, a hydroxyl group-containing group, a hydrolyzable group, or metal salt derivatives thereof; and
R² to R⁴ are each independently substituted or unsubstituted monovalent hydrocarbon groups, hydrogen atoms, halogen atoms, hydroxyl groups, alkoxy groups, or divalent functional groups bonding to binding sites for silicon atoms —O—, in any of the siloxane units represented by R¹₃SiO_{1/2}, R¹₂SiO_{2/2}, R¹SiO_{3/2}, and SiO_{4/2} or silicon atoms Si in the same siloxane unit, at least one of R² to R⁴ being a binding site for oxygen atoms —O— in any of the siloxane units represented by R¹₃SiO_{1/2}, R¹₂SiO_{2/2}, R¹SiO_{3/2}, and SiO_{4/2}; and R¹ is defined above.

3. The surface treatment agent for an optical material according to claim 2, wherein the organic silicon compound is an organic silicon compound represented by the following average structural formula:
(R^{M}₃SiO_{1/2})ₐ(R^{D}₂SiO_{2/2})_{b}(R^{T}SiO_{3/2})_{c}(SiO_{4/2})_{d},
wherein R^{M}, R^{D}, and R^{T} are each independently
monovalent hydrocarbon groups, hydrogen atoms, hydroxyl groups, alkoxy groups, groups having functional groups Q selected from highly polar functional groups, hydroxyl group-containing groups, silicon atom-containing hydrolyzable groups, or metal salt derivatives thereof bonded to silicon atoms directly or via functional groups with a valency of (n+1) represented by —Z-(Q)n defined above, or divalent functional groups bonded to the Si atoms of other siloxane units;
at least 50 mol % of all of the R^{M}, R^{D}, and R^{T} moieties are monovalent hydrocarbon groups;
the groups contain at least one group represented by —Z-(Q)n in the molecule; and n is a number equal to 1 or greater, a to d are respectively 0 or positive numbers, and a+b+c+d is a number within a range of 2 to 1,000.

4. The surface treatment agent for an optical material according to claim 1, wherein the organic silicon compound is an organic silicon compound represented by the following average structural formula:
(R^{M1}₃SiO_{1/2})ₐ₁(R^{D1}₂SiO_{2/2})_{b1}(R^{T1}SiO_{3/2})_{c1}(SiO_{4/2})_{d1},
wherein R^{M1}, R^{D1}, and R^{T1} are each independently selected from:
monovalent hydrocarbon groups, hydrogen atoms, hydroxyl groups, alkoxy groups, groups having a functional group Q selected from highly polar functional groups, hydroxyl group-containing groups, silicon atom-containing hydrolyzable groups, or metal salt derivatives thereof bonded to silicon atoms via divalent functional groups Z¹ represented by —Z¹-Q;
groups represented by -A-(R^{D2}₂SiO)ₑ₁R^{D2}₂Si—Z¹-Q, wherein A is a divalent hydrocarbon group, R^{D2} is an alkyl group or a phenyl group, e1 is a number within the range of 1 to 50, and Z¹ and Q are defined above;
groups represented by -A-(R^{D2}₂SiO)ₑ₁SiR^{M2}₃, wherein A, R^{D2}, Z¹, and Q are defined above, R^{M2} is an alkyl group or a phenyl group, and e1 is defined above; or
groups represented by —O—Si(R^{D3})₂—X¹, wherein R^{D3} is an alkyl group having from 1 to 6 carbon atoms or a phenyl group, and X¹ is a silylalkyl group represented by the following general formula (2) when i=1: 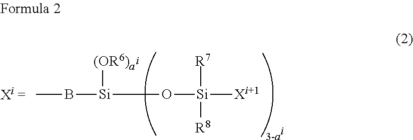
wherein R⁶ is a hydrogen atom or an alkyl group having from 1 to 6 carbon atoms or a phenyl group, and R⁷ or R⁸ is a hydrogen atom or an alkyl group having from 1 to 6 carbon atoms or a phenyl group; B is a straight-chain or branched-chain alkylene group represented by CᵣH₂ᵣ; r is an integer from 2 to 20;
i represents the hierarchies of a silylalkyl group represented by Xⁱ, which is an integer from 1 to c when the number of hierarchies is c; the number of hierarchies c is an integer from 1 to 10; aⁱ is an integer from 0 to 2 when i is 1 and is a number less than 3 when i is 2 or greater; Xⁱ⁺¹ is a silylalkyl group when i is less than c and is a methyl group —CH₃ when i=c;
wherein at least 50% of all of the R^{M1}, R^{D1}, and R^{T1} moieties are monovalent hydrocarbon groups;
the groups contain at least one group represented by —Z-(Q)n or a group represented by -A-(R^{D}₂SiO)ₑ₁R^{D2}₂Si—Z-(Q)n in the molecule;
a1 to d1 are respectively 0 or positive numbers, and a1+b1+c1+d1 is a number within the range from 2 to 500; and the number of silicon atoms in the molecule is within the range of 2 to 1,000.

5. The surface treatment agent for an optical material according to claim 1, wherein the functional group Q bonded to silicon atoms directly or via a functional group with a valency of (n+1), where n is a number equal to 1 or greater, in the organic silicon compound is a carboxyl group, an aldehyde group, a phosphoric acid group, a thiol group, a sulfo group, an alcoholic hydroxyl group, a phenolic hydroxyl group, an amino group, an ester group, an amide group, a polyoxyalkylene group, a silicon atom-containing hydrolyzable group represented by —SiR⁵_{f}X_{3-f}, wherein R⁵ is an alkyl group or an aryl group, X is a hydrolyzable group selected from an alkoxy group, an aryloxy group, an alkenoxy group, an acyloxy group, a ketoxymate group, and a halogen atom, and f is a number from 0 to 2, or a metal salt derivative thereof.

6. The surface treatment agent for an optical material according to claim 1, wherein the functional group bonded to silicon atoms via a functional group with a valency of (n+1), where n is a number equal to 1 or greater, in the organic silicon compound is a group selected from a carboxyl group, an alcoholic hydroxyl group, a polyoxyalkylene group, and a silicon atom-containing hydrolyzable group represented by —SiR⁵_{f}X_{3-f}, wherein R⁵ is an alkyl group or an aryl group, X is a hydrolyzable group selected from an alkoxy group, an alkenoxy group, an aryloxy group, an acyloxy group, a ketoxymate group, and a halogen atom, and f is a number from 0 to 2.

7. The surface treatment agent for an optical material according to claim 1, wherein the functional group bonded to silicon atoms via a functional group with a valency of (n+1), where n is a number equal to 1 or greater, in the organic silicon compound is a carboxyl group or a silicon atom-containing hydrolyzable group represented by —SiR⁵_{f}X_{3-f} bonded to silicon atoms via a divalent hydrocarbon group, wherein R⁵ is an alkyl group or an aryl group, X is a hydrolyzable group selected from an alkoxy group, an aryloxy group, an acyloxy group, a metoxymate group, and a halogen atom, and f is a number from 0 to 2.

8. The surface treatment agent for an optical material according claim 1, wherein the number of silicon atoms in the organic silicon compound is within a range of 2 to 500, and the functional group with a valency of (n+1) or the divalent functional group is a straight-chain or branched-chain alkylene group having from 2 to 20 carbon atoms.

9. The surface treatment agent for an optical material according to claim 1, wherein the surface treatment agent is used on one or more optical fine members selected from fluorescent microparticles, metal oxide microparticles, metal microparticles, nanocrystal structures, and quantum dots, or members in which part or entire surface of these members is covered by a silica layer.

10. An optical material comprising a member which is surface-treated by the surface treatment agent for an optical material according to claim 1.

11. The optical material according to claim 10, wherein the member is a microparticulate member.

12. A production method for an optical material in which a member is a microparticulate member, comprising using the surface treatment agent for an optical material according to claim 1 in at least one production step selected from a liquid-phase method, a solid-phase method, and a post-treatment method.

13. The optical material according to claim 10 comprising: (A) at least one optical fine member selected from fluorescent microparticles, metal oxide microparticles, metal microparticles, nanocrystal structures, and quantum dots or members in which part or entire surface of these members is covered by a silica layer;
(B) the surface treatment agent for an optical material; and
(C) a curable resin composition; wherein
the component (A) microparticles are dispersed in the component (C) curable resin composition after being surface-treated by the component (B) surface treatment agent for an optical material.

14. The optical material according to claim 13, wherein the curable resin composition (C) is a hydrosilylation reaction-curable silicone composition.

15. The optical material according to claim 13, wherein the curable resin composition (C) is a condensation reaction-curable silicone composition.

16. The optical material according to claim 13, further comprising (D) a fluorescent substance.

17. The optical material according to claim 10, which is an optical material for an optical semiconductor.
